(19) United States
(12) Patent Application Publication
(10) Pub. No.: US 2026/0150503 A1
(43) Pub. Date: May 28, 2026

(54) DISPLAY DEVICE

(71) Applicant: LG Display Co., Ltd., Seoul (KR)

(72) Inventors: JaeHee PARK, Paju-si (KR); DongYoon KIM, Paju-si (KR); Taehee KO, Paju-si (KR)

(73) Assignee: LG Display Co., Ltd., Seoul (KR)

(21) Appl. No.: 19/343,790

(22) Filed: Sep. 29, 2025

(30) Foreign Application Priority Data
Nov. 26, 2024 (KR) 10-2024-0170459

(51) Int. Cl. H10K 59/121; G09G 3/3233

(52) U.S. Cl. CPC H10K 59/1216; G09G 3/3233; H10K 59/1213; G09G 2300/0426; G09G 2300/0465; G09G 2300/0852

(57) ABSTRACT

A display device is provided including a substrate having a display area and a transmissive area. A plurality of sub-pixels are disposed in the display area, each sub-pixel comprising a driving thin film transistor having a gate electrode, a source electrode, a drain electrode, and an active layer, and a first electrode electrically connected to the source electrode or the drain electrode. A plurality of capacitors are provided, each including a first capacitor electrode electrically connected to the gate electrode and a second capacitor electrode electrically connected to the source electrode or the drain electrode. The first capacitor electrode and the second capacitor electrode are positioned to overlap each other in the transmissive area, thereby enabling increased capacitor area without enlarging the circuit region, while maintaining transmissive characteristics for light passing through the transmissive area. This arrangement supports improved luminance stability in a compact pixel structure.

### CROSS-REFERENCE TO RELATED APPLICATIONS

This application claims the benefit of the Republic of Korea Patent Application No. 10-2024-0170459 filed on Nov. 26, 2024, each of which is hereby incorporated by reference in its entirety.

### BACKGROUND

### Technical Field

The present disclosure relates to a display device.

### Description of the Related Art

A display device includes a plurality of signal lines and a plurality of thin film transistors connected to the plurality of signal lines.

In some cases, it is necessary to reduce an area in which signal lines and a plurality of thin film transistors are disposed, and in this case, a capacitor area may also be reduced, resulting in a luminance reduction problem due to a decrease in capacitance.

### BRIEF SUMMARY

The present disclosure describes a display device that increases pixel storage capacitance without enlarging the pixel's circuit or line area by relocating a capacitor into the transmissive area (TA) of the display. The capacitor is formed from a first capacitor electrode (Cap1) connected to the driving thin film transistor gate and a second capacitor electrode (Cap2) connected to its source or drain, with both electrodes and their extension portions made from transmissive materials so that light is not blocked. By using available space in the transmissive area, the design increases capacitance and improves luminance stability while maintaining a reduced thin film transistor and circuit area.

A further aspect is the use of the second capacitor electrode extension part (Cap2_EP) in areas where a driving thin film transistor of one sub-pixel overlaps an adjacent sub-pixel. In this arrangement, the extension also serves as an electrostatic shield that prevents parasitic capacitance from causing unintended gate voltage shifts in the driving thin film transistor, thereby avoiding grayscale defects. An additional shielding layer (SL) may be provided for further suppression. This shielding approach enables a high density arrangement of switching, driving, and sensing thin film transistors with partial overlap between sub-pixels, which reduces the circuit area and allows for higher resolution or a larger transmissive area.

Additional features include the integration of a light blocking layer beneath the driving thin film transistor active layer as a capacitor electrode, thereby combining optical shielding with electrical storage in a single structure. The design also provides flexible electrical connection schemes, such as separate sub-electrodes (200a and 200b) driven through separate connection electrodes for repair capability, and variations in material and layer placement for the capacitor electrodes and their extensions to accommodate different routing arrangements. These measures allow adaptation of the pixel structure while preserving the increased capacitance and shielding functions.

Various embodiments of the present disclosure provide a display device configured to increase a capacitor area while reducing an area occupied by signal lines and a thin film transistor, thereby offering a technical solution to a problem in the related art.

In accordance with an aspect of the present disclosure, the above and other technical effects can be accomplished by the provision of a display device comprising a substrate including a display area and a transmissive area, a plurality of sub-pixels disposed in the display area on the substrate, a driving thin film transistor disposed in each of the plurality of sub-pixels and including a gate electrode, a source electrode, a drain electrode, and an active layer, a first electrode disposed in each of the plurality of sub-pixels and electrically connected to the source electrode or the drain electrode, and a plurality of capacitors including a first capacitor electrode electrically connected to the gate electrode, and a second capacitor electrode electrically connected to the source electrode or the drain electrode, wherein the first capacitor electrode and the second capacitor electrode overlap each other in the transmissive area.

In addition, in accordance with an aspect of the present disclosure, the above and other technical effects can be accomplished by the provision of a display device comprising a substrate including a circuit area and a light emitting area, a plurality of sub-pixels on the substrate, a driving thin film transistor disposed in each of the plurality of sub-pixels and including a gate electrode, a source electrode, a drain electrode, and an active layer, a first electrode disposed in each of the plurality of sub-pixels and electrically connected to the source electrode or the drain electrode; and a capacitor including a first capacitor electrode electrically connected to the gate electrode, and a second capacitor electrode electrically connected to the source electrode or the drain electrode, wherein the first capacitor electrode and the second capacitor electrode overlap each other in the light emitting area.

It is to be understood that both the foregoing general description and the following detailed description are exemplary and explanatory and are intended to provide further explanation of the inventive concepts as claimed

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a circuit diagram of an electroluminescent display device according to an embodiment of the present disclosure.

FIG. 2 is a plan view of an electroluminescent display device according to an embodiment of the present disclosure.

FIG. 3 is a cross-sectional view of an electroluminescent display device according to an embodiment of the present disclosure, which corresponds to a cross-section taken along line A-A of FIG. 2.

FIG. 4 is a cross-sectional view of an electroluminescent display device according to an embodiment of the present disclosure, which corresponds to a cross-section taken along line B-B of FIG. 2.

FIG. 5 is a cross-sectional view of an electroluminescent display device according to an embodiment of the present disclosure, which corresponds to a cross section taken along line C-C of FIG. 2.

FIG. 6 is a plan view of an electroluminescent display device according to another embodiment of the present disclosure.

FIG. 7 is a cross-sectional view of an electroluminescent display device according to another embodiment of the present disclosure, which corresponds to a cross-section taken along line A-A of FIG. 6.

FIG. 8 is a cross-sectional view of an electroluminescent display device according to another embodiment of the present disclosure, which corresponds to a cross-section taken along line B-B of FIG. 6.

FIG. 9 is a plan view of an electroluminescent display device according to another embodiment of the present disclosure.

FIG. 10 is a cross-sectional view of an electroluminescent display device according to another embodiment of the present disclosure, which corresponds to a cross-section taken along line A-A of FIG. 9.

FIG. 11 is a cross-sectional view of an electroluminescent display device according to another embodiment of the present disclosure, which corresponds to a cross-section taken along line B-B of FIG. 9.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only˜’ is used. The terms of a singular form may include plural forms unless referred to the contrary.

In interpreting the components, it is interpreted as including the error range even if there is no separate explicit description of the error range.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used. The terms, such as “below,” “lower,” “above,” “upper” and the like, may be used herein to describe a relationship between element(s) as illustrated in the drawings. It will be understood that the terms are spatially relative and based on the orientation depicted in the drawings.

A description of a time relationship may include a case in which the temporal precedence relationship is described as “after”, “following”, or “before”, etc., and is not continuous unless “right away” or “directly”, is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)”, etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” “connected,” or “attached” to another component, that component may be connected, coupled, connected, or attached directly to that other component, but it should be understood that other components may be interposed between each component that may be connected, coupled, connected, or attached indirectly, without any specific description.

It should be understood that if a component or layer is stated to be “in contact” or “overlapping” with another component or layer, the component or layer may be in direct contact or overlapping with another component or layer, but other components may be interposed between each component that may be indirectly in contact or overlapping without particular explicit description.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“First direction”, “second direction”, “third direction”, “X-axis direction”, “Y-axis direction”, and “Z-axis direction” should not be interpreted only as a geometric relationship perpendicular to each other, but may mean that the configuration of the present disclosure has a wider direction within a range in which the configuration of the present disclosure may functionally act.

Features of each of the various embodiments of the present specification may be partially or entirely coupled or combined with each other, technically various interworking and driving are possible, and each of the embodiments may be independently implemented with respect to each other or may be implemented together in a related relationship.

Hereinafter, one embodiment of the present disclosure will be described in detail with reference to the accompanying drawings.

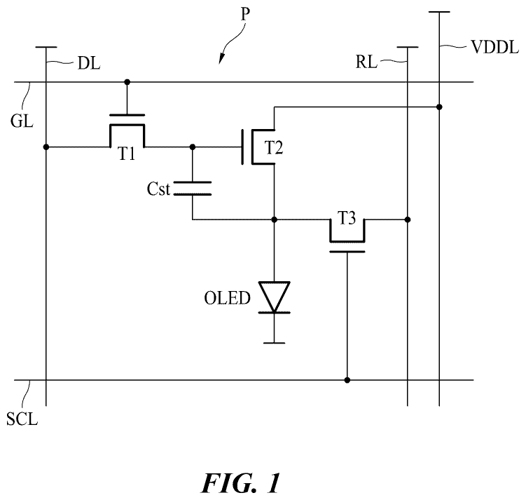

FIG. 1 is a circuit diagram of an electroluminescent display device according to an embodiment of the present disclosure.

As shown in FIG. 1, an electroluminescent display device according to an embodiment of the present disclosure includes a gate line GL, a sensing control line SCL, a high power line VDDL, a data line DL, a reference line RL, a switching thin film transistor T1, a driving thin film transistor T2, a sensing thin film transistor T3, a capacitor Cst, and an organic light emitting diode OLED.

The gate line GL supplies a gate signal to a gate terminal of the switching thin film transistor T1.

The sensing control line SCL supplies a sensing control signal to a gate terminal of the sensing thin film transistor T3. The sensing control line SCL may be omitted, and in this case, the gate terminal of the sensing thin film transistor T3 may be connected to the gate line GL to receive a sensing control signal from the gate line GL.

The high power line VDDL supplies high power to a drain terminal of the driving thin film transistor T2.

The data line DL supplies a data signal to a source terminal of the switching thin film transistor T1.

The reference line RL is connected to a drain terminal of the sensing thin film transistor T3.

The switching thin film transistor T1 is switched according to the gate signal supplied to the gate line GL to supply a data voltage supplied from the data line DL to the driving thin film transistor T2.

The driving thin film transistor T2 is switched according to the data voltage supplied from the switching thin film transistor T1 to generate a data current from the high power source supplied from the high power line VDDL and supplies the data current to the organic light emitting diode OLED.

The sensing thin film transistor T3 senses a threshold voltage deviation of the driving thin film transistor T2, which causes image quality to deteriorate. Such sensing of the threshold voltage deviation may be performed in a sensing mode. The sensing thin film transistor T3 supplies a voltage of the driving thin film transistor T2 to the reference line RL in response to the sensing control signal supplied from the sensing control line SCL.

The capacitor Cst maintains the data voltage supplied to the driving thin film transistor T2 for one frame, and is connected to a gate terminal and a source terminal of the driving thin film transistor T2, respectively.

The organic light emitting diode OLED emits predetermined light according to the data current supplied from the driving thin film transistor T2. The organic light emitting diode OLED includes an anode and a cathode, and a light emitting layer disposed between the anode and the cathode. The anode of the organic light emitting diode OLED is connected to the source terminal of the driving thin film transistor T2, and the cathode of the organic light emitting diode OLED is connected to a low power line. Although not shown, the low power line for supplying low power to the cathode of the organic light emitting diode OLED may be additionally disposed.

In the present disclosure, a power line means at least one of the high power line and the low power line.

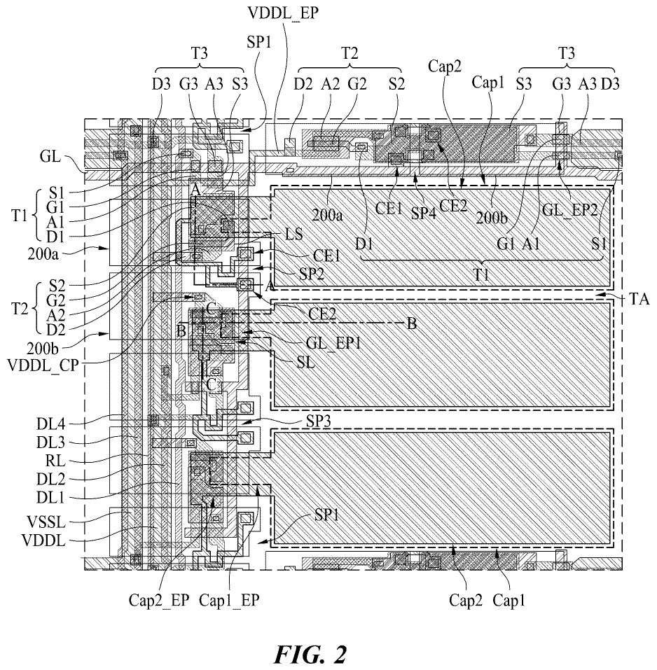

FIG. 2 is a plan view of an electroluminescent display device according to an embodiment of the present disclosure. In FIG. 2, a rectangular shape illustrates a contact hole disposed in the insulating layer so that two overlapping components with the insulating layer therebetween may be electrically connected to each other, which is the same in the following embodiment.

As shown in FIG. 2, a gate line GL is arranged in the first direction, for example, in the horizontal direction.

A first gate line extension part GL_EP1 and a second gate line extension part GL_EP2 may extend from the gate line GL. The gate line extension parts GL_EP1 and GL_EP2 and the gate line GL may be formed as one body.

The first gate line extension part GL_EP1 may extend downward from the gate line GL, and the second gate line extension part GL_EP2 may extend upward from the gate line GL.

The first gate line extension part GL_EP1 may include a first portion and a second portion. The first portion is an area extending downward from one side of the gate line GL in the second direction, for example, in the vertical direction, and the second portion is an area extending from the first portion to the left in the first direction, for example, in the horizontal direction. The first gate line extension part GL_EP1 includes a structure in which a combination of the first portion and the second portion is repeated twice, and thus may be extended to a plurality of sub-pixels arranged in the second direction, for example, a third sub-pixel SP3 and a first sub-pixel SP1.

The second gate line extension part GL_EP2 may extend upward in the second direction from the other side of the gate line GL, and thus may extend to another sub-pixel arranged in the first direction, for example, a fourth sub-pixel SP4.

For example, the gate line GL may supply a gate signal to the second sub-pixel SP2, the first gate line extension part GL_EP1 may supply the same gate signal to the third sub-pixel SP3 and the first sub-pixel SP1, and the second gate line extension part GL_EP2 may supply the same gate signal to the fourth sub-pixel SP4. In this case, the first sub-pixel to the third sub-pixel SP1, SP2, and SP3 may be arranged in the second direction, for example, in the vertical direction, and the fourth sub-pixel SP4 may be arranged in the horizontal direction from the right side of the first sub-pixel, for example.

A high power line VDDL, a low power line VSSL, a data lines DL1, DL2, DL3, and DL4 and a reference line RL are arranged in the second direction crossing the first direction, for example, in the vertical direction.

In the second direction, the fourth data line DL4, the third data line DL3, the reference line RL, the second data line DL2, and the first data line DL1 may be arranged in order, but are not limited thereto.

The first data line DL1 supplies a data signal to the first sub-pixel SP1, the second data line DL2 supplies a data signal to the second sub-pixel SP2, the third data line DL3 supplies a data signal to the third sub-pixel SP3, and the fourth data line DL4 supplies a data signal to the fourth sub-pixel SP4.

The high power line VDDL may overlap the second data line DL2 and the reference line RL, and the low power line VSSL may overlap the third data line DL3 and the fourth data line DL4, but is not limited thereto.

The high power line VDDL may be connected to a high power line connection part VDDL_CP. The high power line connection part VDDL_CP is connected to the high power line VDDL through a contact hole and extends from the high power line VDDL in the first direction. The high power source VDD may be supplied to the plurality of sub-pixels, for example, the first to third sub-pixels, through the high power line connection part VDDL_CP.

In addition, a high power line extension part VDDL_EP may extend from the high power line VDDL. The high power line extension part VDDL_EP may extend from the high power line VDDL to the fourth sub-pixel in the first direction. The high power VDD may be supplied to the fourth sub-pixel through the high power line extension part VDDL_EP.

The data lines DL1, DL2, DL3, and DL4 and the reference line RL may be formed of the same material on the same layer. The data lines DL1, DL2, DL3, and DL4 and the reference line RL may be positioned below the gate line GL with an insulating layer therebetween.

The high power line VDDL and the low power line VSSL may be made of the same material on the same layer. The high power line VDDL and the low power line VSSL may be positioned above the gate line GL with an insulating layer therebetween.

The high power line connection part VDDL_CP may be formed of the same material on the same layer as the gate line GL. The high power line extension part VDDL_EP and the high power line VDDL may be formed as one body.

A first sub-pixel SP1 may be disposed above one side of the gate line GL while partially overlapping the gate line GL, and a second sub-pixel SP2 and a third sub-pixel SP3 may be sequentially disposed below the first sub-pixel SP1. In addition, a fourth sub-pixel SP4 may be disposed above the other side of the gate line GL while partially overlapping the gate line GL. The fourth sub-pixel SP4 may face the first sub-pixel SP1.

The first to third sub-pixels SP1, SP2, and SP3 may overlap the high power line VDDL, the low power line VSSL, the data lines DL1, DL2, DL3, and DL4, and the reference line RL.

The fourth sub-pixel SP4 may not overlap the high power line VDDL, the low power line VSSL, the data lines DL1, DL2, DL3, and DL4, and the reference line RL.

Each of the sub-pixels SP1, SP2, SP3, and SP4 may include a light emitting area, a line area, and a circuit area. In this case, the light emitting area may overlap at least a portion of the line area and the circuit area, and in this case, the electroluminescent display device may be configured in a top emission type.

Throughout the present disclosure, the light emitting area is an area in which light emission occurs, the line area is an area in which lines including the high power line VDDL, the data lines DL1, DL2, DL3, and DL4, the reference line RL, the gate line GL, and the scan control line SCL are disposed, and the circuit area is an area in which thin film transistors T1, T2, and T3 and a capacitor are disposed.

According to an embodiment of the present disclosure, at least a part of the light emitting area, the line area, and the circuit area may constitute a display area in which an image is displayed. In addition, according to an embodiment of the present disclosure, a transmissive area TA may be disposed in an area other than the display area. The transmissive area TA may be disposed at a right area of the second and third sub-pixels SP2 and SP3 and a lower area of the fourth sub-pixel SP4, and external light is transmitted through the transmissive area TA so that a user can see a background behind the display device.

The fourth data line DL4 and the third data line DL3 may be disposed adjacent to each other without other wirings being disposed therebetween. The third data line DL3 and the reference line RL may be disposed adjacent to each other without other wirings being disposed therebetween. The reference line RL and the second data line DL2 may be disposed adjacent to each other without other wirings being disposed therebetween. The second data line DL2 and the first data line DL1 may be disposed adjacent to each other without other wirings being disposed therebetween.

According to another embodiment of the present disclosure, the data lines DL1, DL2, DL3, and DL4 and the reference line RL are disposed adjacent to each other, and the high power line VDDL and the low power line VSSL are disposed adjacent to each other to overlap the data lines DL1, DL2, DL3, and DL4 and the reference line RL.

Thus, according to another embodiment of the present disclosure, various lines are adjacent to each other to form the line area, and the circuit area including a plurality of thin film transistors T1, T2, and T3 is arranged to be adjacent to the line area, thereby reducing the total size of the line area and the circuit area. Accordingly, a resolution can be increased by reducing a size of the light emitting area, and a size of the transmissive area can also be increased.

A switching thin film transistor T1, a driving thin film transistor T2, and a sensing thin film transistor T3 are disposed in the circuit area of each of the four sub-pixels SP1, SP2, SP3, and SP4.

The switching thin film transistor T1 includes a first gate electrode G1, a first source electrode S1, a first drain electrode D1, and a first active layer A1.

The first gate electrode G1 of the second sub-pixel SP2 may include a part of the gate line GL, the first gate electrode G1 of the first sub-pixel SP1 and the third sub-pixel SP3 may include a part of the first gate line extension part GL_EP1, more specifically a part of the second portion of the first gate line extension part GL_EP1 extending in the horizontal direction, and the first gate electrode G1 of the fourth sub-pixel SP4 may include a portion of the second gate line extension part GL_EP2.

The first source electrode S1 may be connected to the data lines DL1, DL2, DL3, and DL4 through a contact hole, and may be connected to one end of the first active layer A1 through a contact hole.

The first drain electrode D1 may be disposed on the same layer as the first source electrode S1, and may be connected to the other end of the first active layer A1 through a contact hole.

The first source electrode S1 and the first drain electrode D1 may be formed of the same material as the first gate electrode G1, but are not limited thereto.

The first active layer A1 may be connected to the first source electrode S1 and the first drain electrode D1 through a contact hole, respectively, to function as an electron moving channel.

The driving thin film transistor T2 includes a second gate electrode G2, a second source electrode S2, a second drain electrode D2, and a second active layer A2.

The second gate electrode G2 may be connected to the first drain electrode D1 of the switching thin film transistor T1. The second gate electrode G2 and the first drain electrode D1 may be formed as one body, but is not limited thereto.

The second source electrode S2 may be connected to one end of the second active layer A2 through a contact hole. The second source electrode S2 may be connected to a light blocking layer LS thereunder through a contact hole.

The light blocking layer LS may be formed of the same material in the same layer as the data lines DL1, DL2, DL3, and DL4, and the reference line RL. The light blocking layer LS may overlap the second active layer A2 to block external light from being incident on the second active layer A2. In addition, the light blocking layer LS may function as a capacitor electrode. Specifically, the light blocking layer LS and the second gate electrode G2 may overlap each other with an insulating layer therebetween, so that a capacitor may be formed by the light blocking layer LS and the second gate electrode G2.

The second source electrode S2 may be connected to two connection electrodes CE1 and CE2 through contact holes. The two connection electrodes CE1 and CE2 may be formed of the same material on the same layer as the high power line VDDL and the low power line VSSL.

Like the first to third sub-pixels SP1, SP2, and SP3, a first connection electrode CE1 may be connected to the second source electrode S2 through a contact hole, and a second connection electrode CE1 may be branched from the first connection electrode CE1. In addition, like the fourth sub-pixel SP4, each of the first connection electrode CE1 and the second connection electrode CE2 may be connected to the second source electrode S2 through a contact hole.

The first connection electrode CE1 may be connected to a first sub-electrode 200a that functions as one anode through a contact hole, and the second connection electrode CE2 may be connected to a second sub-electrode 200b that functions as the other anode through a contact hole. Accordingly, the first electrodes 200a and 200b of one sub-pixel may be formed of two sub-electrodes 200a and 200b that are spaced apart from each other. The two sub-electrodes 200a and 200b may be driven at the same time, or only one sub-electrode 200a and 200b may be driven by a repair process for solving defects.

The second drain electrode D2 may be connected to the other end of the second active layer A2 through a contact hole.

Like the first to third subpixels SP1, SP2, and SP3, the second drain electrode D2 may be connected to the high power line VDDL through a high power line connection part VDDL_CP. The high power line connection part VDDL_CP is connected to the high power line VDDL through a contact hole. The high power line connection part VDDL_CP may be connected to the second drain electrode D2 of the first to third subpixels SP1, SP2, and SP3 while extending in the first direction. The high power line connection part VDDL_CP and the second drain electrode D2 may be formed as one body.

Like the fourth sub-pixel SP4, the second drain electrode D2 may be connected to the high power line VDDL through a high power line extension part VDDL_EP. The high power line extension part VDDL_EP and the high power line VDDL may be formed as one body. The high power line extension part VDDL_EP may be connected to the second drain electrode D2 through a contact hole.

The second source electrode S2 and the second drain electrode D2 may be formed of the same material as the second gate electrode G2, but are not limited thereto.

In some cases, a configuration connected to the high power line VDDL through the high power line connection part VDDL_CP or the high power line extension part VDDL_EP may function as a source electrode, and a configuration connected to the first electrodes 200a and 200b through the connection electrodes CE1 and CE2 may function as a drain electrode.

The second active layer A2 may be connected to the second source electrode S2 and the second drain electrode D2 through a contact hole, respectively, to function as an electron moving channel. The second active layer A2 may be formed of the same material on the same layer as the first active layer A1.

The sensing thin film transistor T3 includes a third gate electrode G3, a third source electrode S3, a third drain electrode D3, and a third active layer A3.

The third gate electrode G3 of the second sub-pixel SP2 may include a portion of the gate line GL, the third gate electrode G3 of the first sub-pixel SP1 and the third sub-pixel SP3 may include a portion of the first gate line extension part GL_EP1, specifically a portion of the second portion of the first gate line extension part GL_EP1, and the third gate electrode G3 of the fourth sub-pixel SP4 may include a portion of the second gate line extension part GL_EP2.

The third source electrode S3 may be formed as one body with the second source electrode S2 of the driving thin film transistor T2. Alternatively, the third source electrode S3 may be connected to the light blocking layer LS through a contact hole, and thus may be electrically connected to the second source electrode S2 of the driving thin film transistor T2 through the light blocking layer LS.

The third source electrode S3 may be connected to one end of the third active layer A3 through a contact hole.

The third drain electrode D3 may be formed of the same material on the same layer as the third source electrode S3, and may be connected to the other end of the third active layer A3 through a contact hole. In addition, the third drain electrode D3 may be connected to the reference line RL through a contact hole. One third drain electrode D3 may be shared in the first sub-pixel SP1, the second sub-pixel SP2, and the fourth sub-pixel SP4, and a separate third drain electrode D3 that is not shared with the other sub-pixels SP1, SP2, and SP4 may be disposed in the third sub-pixel SP3.

The third active layer A3 may be connected to the third source electrode S3 and the third drain electrode D3 through a contact hole, respectively, to function as an electron moving channel. The third active layer A3 may be formed of the same material on the same layer as the first active layer A1.

According to an embodiment of the present disclosure, a plurality of capacitors are disposed in the transmissive area TA.

The capacitor includes a first capacitor electrode Cap1 and a second capacitor electrode Cap2 overlapping each other.

The first capacitor electrode Cap1 is electrically connected to the second gate electrode G2 of the driving thin film transistor T2. For example, the first capacitor electrode Cap1 is electrically connected to the second gate electrode G2 of the driving thin film transistor T2 through a first capacitor electrode extension part Cap1_EP.

The first capacitor electrode extension part Cap1_EP extends from the transmissive area TA to the display area. For example, one end of the first capacitor electrode extension part Cap1_EP may be connected to the first capacitor electrode Cap1 in the transmissive area TA, and the other end of the first capacitor electrode extension part Cap1_EP may be connected to the second gate electrode G2 of the driving thin film transistor T2 through a contact hole in the display area. Alternatively, the other end of the first capacitor electrode extension part Cap1_EP may be connected to the drain electrode D1 of the switching thin film transistor T1 through a contact hole in the display area, thereby being electrically connected to the second gate electrode G2 of the driving thin film transistor T2.

The first capacitor electrode Cap1 and the first capacitor electrode extension part Cap1_EP may be formed as one body. The first capacitor electrode Cap1 and the first capacitor electrode extension portion Cap1_EP are formed of a transmissive electrode through which light may pass. The first capacitor electrode Cap1 and the first capacitor electrode extension part Cap1_EP may be formed of the same material in the same layer as the second active layer A2, for example, an oxide semiconductor material.

The second capacitor electrode Cap2 is electrically connected to the second source electrode S2 or the drain electrode D2 of the driving thin film transistor T2. For example, the second capacitor electrode Cap2 is electrically connected to the second source electrode S2 or the drain electrode D2 of the driving thin film transistor T2 through a second capacitor electrode extension part Cap2_EP.

The second capacitor electrode extension part Cap2_EP extends from the transmissive area TA to the display area. For example, one end of the second capacitor electrode extension part Cap2_EP may be connected to the second capacitor electrode Cap2 in the transmissive area TA, and the other end of the second capacitor electrode extension part Cap2_EP may be connected to the second source electrode S2 or the drain electrode D2 of the driving thin film transistor T2 through a contact hole in the display area.

The second capacitor electrode Cap2 and the second capacitor electrode extension part Cap2_EP may be formed as one body with each other. The second capacitor electrode Cap2 and the second capacitor electrode extension part Cap2_EP are formed of a transmissive electrode through which light may pass. The second capacitor electrode Cap2 and the second capacitor electrode extension part Cap2_EP may be formed of the same material as the connection electrodes CE1 and CE2, for example, a metal oxide such as ITO. The second capacitor electrode Cap2 and the second capacitor electrode extension part Cap2_EP may be connected to the first connection electrode CE1. The second capacitor electrode Cap2 and the second capacitor electrode extension part Cap2_EP may be formed as one body with the connection electrodes CE1 and CE2.

The second capacitor electrode Cap2 may overlap the first capacitor electrode Cap1 in the transmissive area TA, and the second capacitor electrode extension part Cap2_EP may overlap the first capacitor electrode extension part Cap1_EP in the transmissive area TA and the display area.

The capacitor including the capacitor electrodes Cap1 and Cap2 and the capacitor electrode extension parts Cap1, EP, and Cap2_EP may be disposed for each of the sub-pixels SP1, SP2, and SP3. Although three capacitors individually connected to the first to third sub-pixels SP1 to SP3 are shown in the drawing, the present disclosure is not limited thereto, and a capacitor connected to the fourth sub-pixel SP4 may be additionally disposed in the transmissive area TA.

In the case of three capacitors individually connected to the first to third subpixels SP1 to SP3, the capacitor electrode extension parts Cap1_EP and Cap2_EP may extend in a left direction from the capacitor electrodes Cap1 and Cap2, and the second capacitor electrode extension part Cap2_EP may be connected to one of the two connection electrodes CE1 and CE2, for example, the first connection electrode CE1.

As described above, in accordance with an embodiment of this disclosure, since the capacitor is disposed to have a large area in the transmissive area TA, a capacitance of the capacitor can be increased, so that a luminance increase effect can be obtained.

According to an embodiment of the present disclosure, the thin film transistors T1, T2, and T3 may be formed in the first to third sub-pixels SP1, SP2, and SP3 at the highest density possible. Accordingly, a size of the circuit area may be minimized. In addition, a resolution may be improved by reducing sizes of the first to third sub-pixels SP1, SP2, and SP3.

For example, according to an embodiment of the present disclosure, since the thin film transistors T1, T2, and T3 are formed in a high density in the plurality of sub-pixels SP1, SP2, and SP3, at least a portion of the thin film transistors T1, T2, and T3 of one sub-pixel may be formed to overlap the other sub-pixel SP1, SP2, and SP3 areas adjacent thereto.

For example, at least a portion of the switching thin film transistor T1 of the second sub-pixel SP2 may be formed to overlap the first sub-pixel SP1. Alternatively, at least a portion of the sensing thin film transistor T3 of the second sub-pixel SP2 may be formed to overlap the first sub-pixel SP1.

Alternatively, at least a portion of the driving thin film transistor T2 of the third sub-pixel SP3 may be formed to overlap an area of the second sub-pixel SP2. Alternatively, at least a portion of the driving thin film transistor T2 of the first sub-pixel SP1 may be formed to overlap an area of the third sub-pixel SP3.

On the other hand, when at least a portion of one sub-pixel driving thin film transistor T2 overlaps with another sub-pixel area adjacent thereto, a parasitic capacitance is generated between the driving thin film transistor T2 of one sub-pixel and the first electrodes 200a and 200b of the other sub-pixel, for example, the second sub-electrode 200b.

For example, when at least a portion of the driving thin film transistor T2 of the third sub-pixel SP3 overlaps an area of the second sub-pixel SP2, a parasitic capacitance may be generated between the driving thin film transistor T2 of the third sub-pixel SP3 and the second sub-electrode 200b of the second sub-pixel SP2. Accordingly, a gate voltage of the driving thin film transistor T2 of the third sub-pixel SP3 increases, and when the third sub-pixel SP3 emits light, a luminance increases, resulting in a gray scale defect.

Accordingly, according to an embodiment of the present disclosure, the second capacitor electrode extension part Cap2_EP is disposed in an area where at least a portion of the driving thin film transistor T2 of the one sub-pixel overlaps an area of the other sub-pixel adjacent thereto, so that the second capacitor electrode extension part Cap2_EP may additionally perform a shielding function to prevent a parasitic capacitance.

Meanwhile, since parasitic capacitance may be generated between the second capacitor electrode extension part Cap2_EP and the first electrode 200a and 200b of another sub-pixel, for example, the second sub-electrode 200b, a shielding layer SL may be additionally disposed in an area overlapping the second capacitor electrode extension part Cap2_EP and the another sub-pixel area. For example, a shielding layer may be additionally disposed on at least a portion of the driving thin film transistor T2 of the third sub-pixel SP3 overlapping an area of the second sub-pixel SP2.

The shielding layer SL may be disposed on the second capacitor electrode extension part Cap2_EP. However, the shielding layer SL may be omitted.

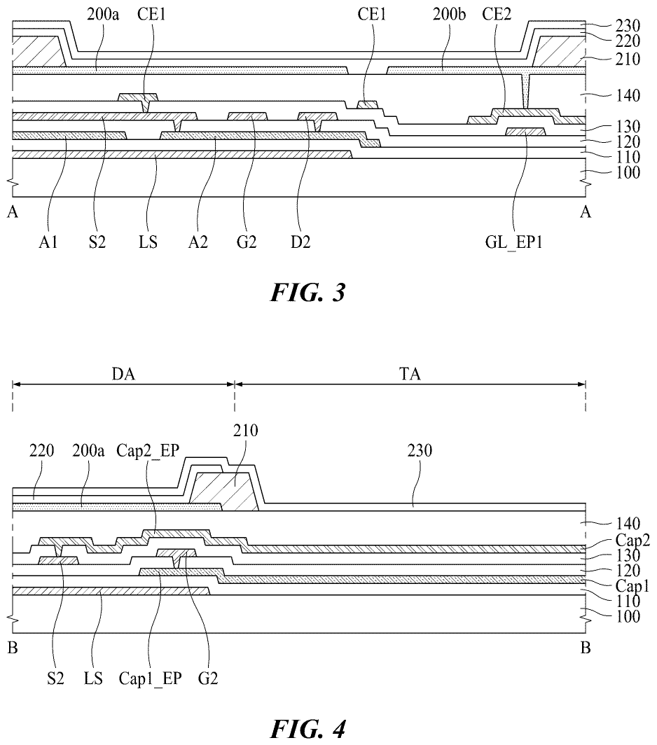

FIG. 3 is a cross-sectional view of an electroluminescent display device according to an embodiment of the present disclosure, which corresponds to a cross-section taken along line A-A of FIG. 2.

As shown in FIG. 3, a light blocking layer LS is disposed on the substrate 100.

The substrate 100 may be made of glass or plastic, but is not limited thereto. The electroluminescent display device according to an embodiment of the present disclosure may be made of a top emission type, and accordingly, a transparent material may be used as a material of the substrate 100.

A first insulating layer 110 is disposed on the light blocking layer LS. The first insulating layer 110 may be formed of an inorganic insulating material.

A second active layer A2 and a first active layer A1 are disposed on the first insulating layer 110.

At least a portion of the second active layer A2 and the first active layer A1 may overlap the light blocking layer LS, so that light entering under the substrate 100 may be blocked by the light blocking layer LS to prevent the light from entering at least a portion of the second active layer A2 and the first active layer A1.

A second insulating layer 120 is disposed on the second active layer A2 and the first active layer A1.

The second insulating layer 120 may be disposed on the entire surface of the substrate 100 except for a contact hole area. However, the present disclosure is not limited thereto, and the second insulating layer 120 may be formed in the same pattern as the second source electrode S2, the second gate electrode G2, the second drain electrode D2, and the first gate line extension part GL_EP except for the contact hole area.

The second insulating layer 120 may be made of an inorganic insulating material.

A second source electrode S2, a second gate electrode G2, a second drain electrode D2, and a first gate line extension portion GL_EP are disposed on the second insulating layer 120 to be spaced apart from each other.

The second source electrode S2 overlaps the second active layer A2, and is connected to one end of the second active layer A2 through a contact hole disposed in the second insulating layer 120. The second source electrode S2 may overlap the first active layer A1, but is not connected to the first active layer A1.

The second gate electrode G2 overlaps the second active layer A2, and is disposed in an area between the second drain electrode D2 and the second source electrode S2.

The second drain electrode D2 overlaps the second active layer A2, and is connected to the other end of the second active layer A2 through a contact hole disposed in the second insulating layer 120.

The first gate line extension part GL_EP may be disposed not to overlap the first active layer A1 and the second active layer A2.

The second source electrode S2, the second gate electrode G2, the second drain electrode D2, and the first gate line extension part GL_EP may be patterned using the same material through the same process in the same layer.

A third insulating layer 130 may be disposed on the second source electrode S2, the second gate electrode G2, the second drain electrode D2, and the first gate line extension part GL_EP.

The third insulating layer 130 may be disposed on an entire surface of the substrate 100 except for a contact hole area. The third insulating layer 130 may be made of an inorganic insulating material.

A first connection electrode CE1 and a second connection electrode CE2 are disposed on the third insulation layer 130.

The first connection electrode CE1 and the second connection electrode CE2 may be patterned using the same material through the same process in the same layer.

The first connection electrode CE1 may be connected to the second source electrode S2 through a contact hole disposed in the third insulating layer 130.

The second connection electrode CE2 may overlap the first gate line extension part GL_EP.

A fourth insulation layer 140 is disposed on the first connection electrode CE1 and the second connection electrode CE2.

The fourth insulating layer 140 may include a planarization layer made of an organic insulating material. The fourth insulating layer 140 may be formed of a plurality of insulating layers, and for example, may have a two-layer structure including a passivation layer made of an inorganic material and a planarization layer made of an organic material.

Meanwhile, although not shown, the fourth insulating layer 140 may be made of an inorganic insulating material, and a fifth insulating layer functioning as a planarization layer made of an organic insulating material may be disposed on the fourth insulating layer 140.

A first electrode 200a and 200b is disposed on the fourth insulation layer 140.

Each of the first electrodes 200 a and 200 b may include a first sub-electrode 200a and a second sub-electrode 200b that are spaced apart from each other while functioning as an anode. The second sub-electrode 200b is connected to the second connection electrode CE2 through a contact hole disposed on the fourth insulation layer 140.

The first electrodes 200a and 200b may include reflective electrodes. Accordingly, light emitted from the light emitting layer 220 may be reflected from the first electrodes 200a and 200b and may proceed in an upward direction.

A bank 210 is disposed on the first electrodes 200a and 200b, a light emitting layer 220 is disposed on the bank 210, and a second electrode 230 is disposed on the light emitting layer 220.

The bank 210, the light emitting layer 220, and the second electrode 230 are the same as those in the above-described embodiment.

In addition, as in the above-described embodiment, an encapsulation layer, a color filter, and a touch sensor may be additionally configured on the second electrode 230.

FIG. 4 is a cross-sectional view of an electroluminescent display device according to an embodiment of the present disclosure, which corresponds to a cross-section taken along line B-B of FIG. 2.

As can be seen from FIG. 4, a light blocking layer LS is disposed on the substrate 100, and a first insulating layer 110 is disposed on the light blocking layer LS.

A first capacitor electrode Cap1 and a first capacitor electrode extension portion Cap1_EP are disposed on the first insulating layer 110. The first capacitor electrode extension part Cap1_EP extends from a display area DA to a transmissive area TA, and the first capacitor electrode Cap1 is disposed in the transmissive area TA. The first capacitor electrode Cap1 and the first capacitor electrode extension part Cap1_EP are formed as one body.

A second insulating layer 120 is disposed on the first capacitor electrode Cap1 and the first capacitor electrode extension part Cap1_EP, and a second source electrode S2 and a second gate electrode G2 of the driving thin film transistor are disposed on the second insulating layer 120.

The second gate electrode G2 is connected to the first capacitor electrode extension part Cap1_EP through a contact hole disposed in the second insulating layer 120 in the display area DA.

A third insulating layer 130 is disposed on the second source electrode S2 and the second gate electrode G2, and a second capacitor electrode Cap2 and a second capacitor electrode extension part Cap2_EP is disposed on the third insulating layer 130.

The second capacitor electrode extension part Cap2_EP extends from the display area DA to the transmissive area TA, and the second capacitor electrode Cap2 is disposed in the transmissive area TA. The second capacitor electrode Cap2 and the second capacitor electrode extension part Cap2_EP are formed as one body.

The second capacitor electrode extension part Cap2_EP is connected to the second source electrode S2 of the driving thin film transistor through a contact hole disposed in the third insulating layer 130 in the display area DA. In some cases, the second capacitor electrode extension part Cap2_EP may be connected to the second drain electrode D2 of the driving thin film transistor through a contact hole disposed in the third insulating layer 130 in the display area DA.

The second capacitor electrode extension part Cap2_EP overlaps the first capacitor electrode extension part Cap1_EP in the display area DA, and the second capacitor electrode Cap2 overlaps the first capacitor electrode Cap1 in the transmissive area TA.

A fourth insulating layer 140 is disposed on the second capacitor electrode Cap2 and the second capacitor electrode extension part Cap2_EP. Although not shown, a fifth insulating layer may be additionally disposed on the fourth insulating layer 140.

A first sub-electrode 200a is disposed on the fourth insulating layer 140, and a bank 210 is disposed on the first sub-electrode 200a while covering an end of the first sub-electrode 200a. The bank 210 may be disposed in a boundary area between the display area DA and the transmissive area TA.

A light emitting layer 220 is disposed on the first sub-electrode 200a, and a second electrode 230 is disposed on the light emitting layer 220.

The light emitting layer 220 may extend on the bank 210, and in some cases, may extend to the transmissive area TA. The second electrode 230 extends from the display area DA to the transmissive area TA.

In addition, as in the above-described embodiment, an encapsulation layer, a color filter, and a touch sensor may be additionally disposed on the second electrode 230.

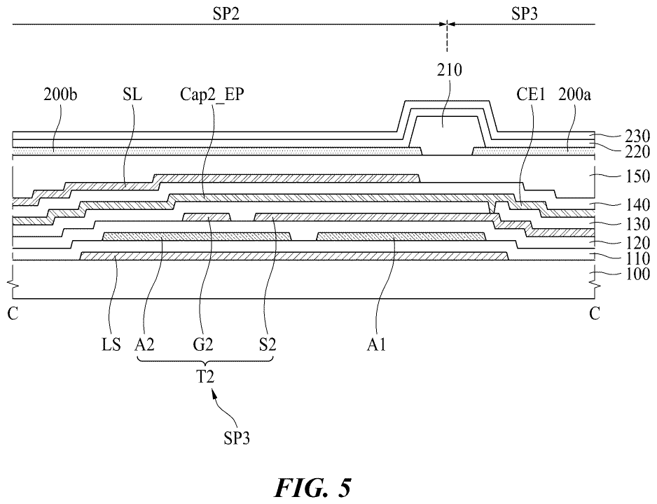

FIG. 5 is a cross-sectional view of an electroluminescent display device according to an embodiment of the present disclosure, which corresponds to a cross section taken along line C-C of FIG. 2.

As can be seen from FIG. 5, a light blocking layer LS is disposed on the substrate 100, and a first insulating layer 110 is disposed on the light blocking layer LS.

A second active layer A2 and a first active layer A1 are disposed on the first insulating layer 110, and a second insulating layer 120 is disposed on the second active layer A2 and the first active layer A1.

A second gate electrode G2 and a second source electrode S2 may be disposed on the second insulating layer 120, and a third insulating layer 130 may be disposed on the second gate electrode G2 and the second source electrode S2.

A second capacitor electrode extension part Cap2_EP and a first connection electrode CE1 are disposed on the third insulation layer 130.

The second capacitor electrode extension part Cap2_EP and the first connection electrode CE1 are formed as one body.

The second active layer A2, the second gate electrode G2, and the second source electrode S2 constitute the driving thin film transistor T2 of the third sub-pixel SP3, and at least a portion of the second active layer A2, the second gate electrode G2, and the second source electrode S2 is disposed in an area of the second sub-pixel SP2.

That is, at least a portion of the driving thin film transistor T2 of the third sub-pixel SP3 is disposed in the area of the second sub-pixel SP2.

The second capacitor electrode extension part Cap2_EP formed as one body with the first connection electrode CE1 of the third sub-pixel SP3 extends from the third sub-pixel SP3 to the second sub-pixel SP2 to overlap at least a portion of the driving thin film transistor T2 of the third sub-pixel SP3 formed in the area of the second sub-pixel SP2.

The second capacitor electrode extension part Cap2_EP is disposed between at least a portion of the driving thin film transistor T2 of the third sub-pixel SP3 and the first electrode 200b of the second sub-pixel SP2, thereby preventing a parasitic capacitance between the driving thin film transistor T2 of the third sub-pixel SP3 and the first electrode 200b of the second sub-pixel SP2, specifically, the second sub-electrode 200b. That is, the second capacitor electrode extension part Cap2_EP may function as a shielding layer.

For example, the second capacitor electrode extension part Cap2_EP may overlap the second active layer A2, the second gate electrode G2, and the second source electrode S2 of the driving thin film transistor T2 of the third sub-pixel SP3 formed in an area of the second sub-pixel SP2. Although not shown, the second capacitor electrode extension part Cap2_EP may overlap the second drain electrode D2 of the driving thin film transistor T2 of the third sub-pixel SP3 formed in the area of the second sub-pixel SP2.

The first connection electrode CE1 may be connected to the second source electrode S2 through a contact hole disposed in the third insulating layer 130.

A fourth insulating layer 140 is disposed on the second capacitor electrode extension part Cap2_EP and the first connection electrode CE1, and a shielding layer SL is formed on the fourth insulating layer 140.

The shielding layer SL is disposed in the second sub-pixel SP2. The shielding layer SL is disposed between the second capacitor electrode extension part Cap2_EP extending to the second sub-pixel SP2 and the first electrode 200b of the second sub-pixel SP2, thereby a preventing parasitic capacitance between the second capacitor electrode extension part Cap2_EP and the first electrode 200b of the second sub-pixel SP2.

A fifth insulating layer 150 is disposed on the shielding layer SL, and a second sub-electrode 200b of the second sub-pixel SP2 and a first sub-electrode 200a of the third sub-pixel SP3 are disposed on the fifth insulating layer 150.

A bank 210 is disposed between the second sub-electrode 200b of the second sub-pixel SP2 and the first sub-electrode 200a of the third sub-pixel SP3.

A light emitting layer 220 is disposed on the sub-electrodes 200 a and 200b and the bank 210, and a second electrode 230 is disposed on the light emitting layer 220.

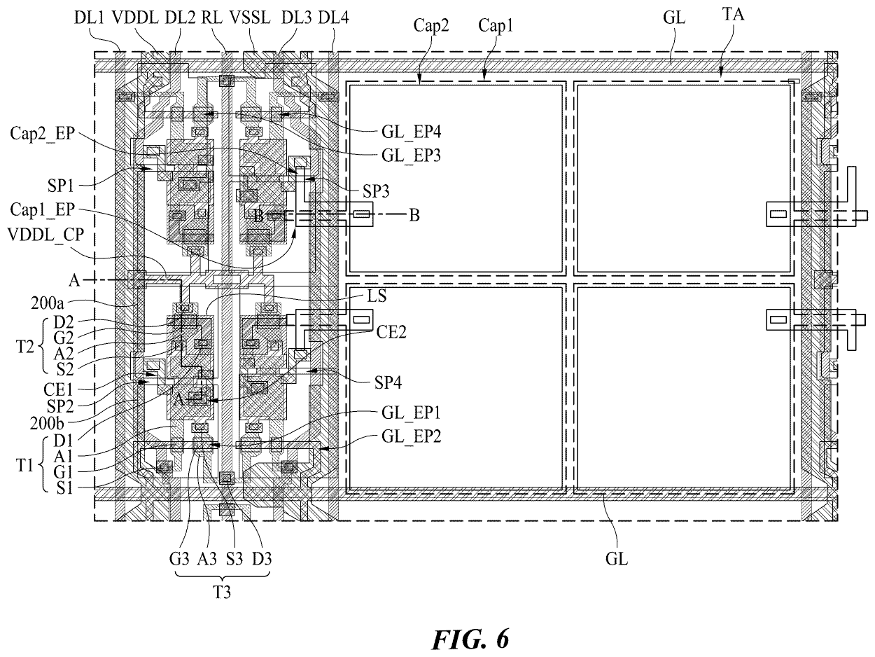

FIG. 6 is a plan view of an electroluminescent display device according to another embodiment of the present disclosure.

As shown in FIG. 6, a plurality of gate lines GLs are arranged in the first direction, for example, in the horizontal direction.

A plurality of gate line extension parts GL_EP1, GL_EP2, GL_EP3, and GL_EP4 are connected to each of the plurality of gate lines GLs. At least a part of the gate line extension part GL_EP1, GL_EP2, GL_EP3, and GL_EP4 extend in a direction different from that of the gate line GL. The gate line extension parts GL_EP1, GL_EP2, GL_EP3, and GL_EP4 may be formed as one body with the gate line GL.

A first gate line extension part GL_EP1 and a second gate line extension part GL_EP2 may extend upward from one gate line GL, and a third gate line extension part GL_EP3 and a fourth gate line extension part GL_EP4 may extend downward from one gate line GL.

For convenience, in FIG. 6, only the third and fourth gate line extension parts GL_EP3 and GL_EP4 are extended to an upper gate line GL, and only the first and second gate line extensions GL_EP1 and GL_EP2 are extended to a lower gate line GL.

The first gate line extension part GL_EP1 may extend upward in the second direction crossing the first direction at one side of the gate line GL, for example, in the vertical direction, and then may extend again to a right along the first direction.

The second gate line extension part GL_EP2 may extend upward in the second direction from the other side of the gate line GL, and then may extend to a left along the first direction.

One end of the first gate line extension part GL_EP1 and one end of the second gate line extension part GL_EP2 may be spaced apart from each other while facing each other with the reference line RL interposed therebetween, and thus, aperture ratio, sharpness, and transparency may be improved compared to a case where they are connected to each other. However, the present disclosure is not necessarily limited thereto, and the first gate line extension part GL_EP1 and the second gate line extension part GL_EP2 may be connected to each other.

The third gate line extension part GL_EP3 may extend downward in the second direction crossing the first direction at one side of the gate line GL, for example, in the vertical direction, and then may extend again to the right along the first direction.

The fourth gate line extension part GL_EP4 may extend downward in the second direction from the other side of the gate line GL and then may extend to the left again along the first direction.

One end of the third gate line extension part GL_EP3 and one end of the fourth gate line extension part GL_EP4 may be spaced apart from each other while facing each other with the reference line RL interposed therebetween, and thus, aperture ratio, sharpness, and transparency may be improved compared to a case where they are connected to each other. However, the present disclosure is not necessarily limited thereto, and the third gate line extension part GL_EP3 and the fourth gate line extension part GL_EP4 may be connected to each other.

The gate line extension parts GL_EP1, GL_EP2, GL_EP3, and GL_EP4 may be disposed in separate sub-pixels.

The first gate line extension part GL_EP1 may supply a gate signal to the second sub-pixel SP2, the second gate line extension part GL_EP2 may supply a gate signal to the fourth sub-pixel SP4, the third gate line extension part GL_EP3 may supply a gate signal to the first sub-pixel SP1, and the fourth gate line extension part GL_EP4 may supply a gate signal to the third sub-pixel SP3.

A high power line VDDL, a low power line VSSL, a data lines DL1, DL2, DL3, and DL4 and a reference line RL are arranged in the second direction crossing the first direction, for example, in the vertical direction.

In the second direction, a first data line DL1, a second data line DL2, the reference line RL, a third data line DL3, and a fourth data line DL4 are arranged in order, and the arrangement may be repeated, but is not limited thereto.

The high power line VDDL may overlap the first data line DL1 and the second data line DL2, and the low power line VSSL may overlap the third data line DL3 and the fourth data line DL4.

The high power line VDDL may be connected to a high power line connection part VDDL_CP. The high power line connection part VDDL_CP is connected to the high power line VDDL through a contact hole and extends from the high power line VDDL in the first direction. The high power source VDD may be supplied to the plurality of sub-pixels SP1, SP2, SP3, and SP4 through the high power line connection part VDDL_CP.

The data lines DL1, DL2, DL3, and DL4 and the reference line RL may be formed of the same material on the same layer. The data lines DL1, DL2, DL3, and DL4 and the reference line RL may be positioned below the gate line GL with an insulating layer therebetween.

The high power line VDDL and the low power line VSSL may be made of the same material on the same layer. The high power line VDDL and the low power line VSSL may be positioned above the gate line GL with an insulating layer therebetween.

The high power line connection part VDDL_CP may be made of the same material on the same layer as the gate line GL.

Two sub-pixels SP1 and SP2 are disposed in the vertical direction between the high power line VDDL and the reference line RL or between the second data line DL2 and the reference line RL. In this case, the two sub-pixels SP1 and SP2 may include a first sub-pixel SP1 and a second sub-pixel SP2 separated from each other with the high power line connection part VDDL_CP interposed therebetween. For example, the two sub-pixels SP1 and SP2 may include a first sub-pixel SP1 disposed above the high power line connection part VDDL_CP and a second sub-pixel SP2 disposed below the high power line connection part VDDL_CP.

In addition, two sub-pixels SP3 and SP4 different in the vertical direction are disposed between the reference line RL and the low power line VSSL or between the low power line VSSL and the third data line DL3. In this case, the other two sub-pixels may include a third sub-pixel SP3 disposed above the high power line connection part VDDL_CP and a fourth sub-pixel SP4 disposed below the high power line connection part VDDL_CP.

In this case, the first sub-pixel SP1 faces the third sub-pixel SP3 with the reference line RL interposed therebetween, and the second sub-pixel SP2 faces the fourth sub-pixel SP4 with the reference line RL interposed therebetween.

Accordingly, four sub-pixels SP1, SP2, SP3, and SP4 may be formed by the high power line VDDL, the reference line RL, and the low power line VSSL arranged in the second direction and the high power line connection unit VDDL_CP arranged in the first direction.

Each of the sub-pixels SP1, SP2, SP3, and SP4 may include a light emitting area, a line area, and a circuit area. In this case, the light emitting area may overlap at least a portion of the line area and the circuit area, and in this case, the electroluminescent display device may be configured in a top emission type.

According to another embodiment of the present disclosure, at least a part of the light emitting area, the line area, and the circuit area may constitute a display area in which an image is displayed. In addition, according to another embodiment of the present disclosure, a transmissive area TA may be disposed in an area other than the display area. The transmissive area TA may be disposed on one side, for example, on a right side of the sub-pixels SP1, SP2, SP3, and SP4, and external light is transmitted through the transmissive area TA so that a user can see a background behind the display device. The transmissive area TA may be defined by a fourth data line DL4 of one pixel, a first data line DL1 of another pixel, and two upper and lower gate lines GL.

The first data line DL1 and the second data line DL2 may be disposed adjacent to each other without other wirings being disposed therebetween. The third data line DL3 and the fourth data line DL4 may also be disposed adjacent to each other without other wirings being disposed therebetween.

The first data line DL1 supplies a data signal to the first sub-pixel SP1, the second data line DL2 supplies a data signal to the second sub-pixel SP2, the third data line DL3 supplies a data signal to the third sub-pixel SP3, and the fourth data line DL4 supplies a data signal to the fourth sub-pixel SP4.

Meanwhile, although not shown, according to another embodiment of the present disclosure, the second data line DL2 is disposed on a left side of the reference line RL while being adjacent to the reference line RL, and the third data line DL3 is disposed on the right side of the reference line RL while being adjacent to the reference line RL, so that the first sub-pixel SP1 and the second sub-pixel SP2 are disposed between the first data line DL1 and the second data line DL2, and the third sub-pixel SP3 and the fourth sub-pixel SP4 may be disposed between the third data line DL3 and the fourth data line DL4.

In addition, although not shown, according to another embodiment of the present disclosure, the high power line VDDL is disposed on a left side of the first data line DL1, the low power line VSSL is disposed on a right side of the fourth data line DL4, the second data line DL2 is disposed on the left side of the reference line RL while being adjacent to the reference line RL, and the third data line DL3 is disposed on the right side of the reference line RL while being adjacent to the reference line RL. The first sub-pixel SP1 and the second sub-pixel SP2 are disposed between the first data line DL1 and the second data line DL2, and the third sub-pixel SP3 and the fourth sub-pixel SP4 may be disposed between the third data line DL3 and the fourth data line DL4, and in this case, the high power line VDDL and the low power line VSSL may be formed of the same material in the same layer as the data lines DL1, DL2, DL3, and DL4 without overlapping the data lines DL1, DL2, DL3, and DL4.

A switching thin film transistor T1, a driving thin film transistor T2, and a sensing thin film transistor T3 are disposed in the circuit area of each of the four sub-pixels SP1, SP2, SP3, and SP4.

The switching thin film transistor T1 includes a first gate electrode G1, a first source electrode S1, a first drain electrode D1, and a first active layer A1.

The first gate electrode G1 may be formed of a part of the gate line extension parts GL_EP1, GL_EP2, GL_EP3, and GL_EP4.

The first source electrode S1 may be connected to a portion branched from the data lines DL1, DL2, DL3, and DL4 through a contact hole, and may be connected to one end of the first active layer A1 through a contact hole.

The first drain electrode D1 may be disposed on the same layer as the first source electrode S1, and may be connected to the other end of the first active layer A1 through a contact hole.

The first source electrode S1 and the first drain electrode D1 may be formed of the same material as the first gate electrode G1, but are not limited thereto.

The first active layer A1 may be connected to the first source electrode S1 and the first drain electrode D1 through a contact hole, respectively, to function as an electron moving channel.

The driving thin film transistor T2 includes a second gate electrode G2, a second source electrode S2, a second drain electrode D2, and a second active layer A2.

The second gate electrode G2 may be connected to the first drain electrode D1 of the switching thin film transistor T1. The second gate electrode G2 may be formed as one body with the first drain electrode D1, but is not limited thereto.

The second source electrode S2 may be connected to one end of the second active layer A2 through a contact hole while facing the second drain electrode D2. The second source electrode S2 may be connected to a light blocking layer LS thereunder through a contact hole.

The light blocking layer LS may be formed of the same material in the same layer as the data lines DL1, DL2, DL3, and DL4, and the reference line RL. The light blocking layer LS may overlap the second active layer A2 to block external light from being incident on the second active layer A2. In addition, the light blocking layer LS may function as a capacitor electrode. Specifically, the light blocking layer LS and the second gate electrode G2 may overlap each other with an insulating layer therebetween, so that a capacitor may be formed by the light blocking layer LS and the second gate electrode G2.

The second source electrode S2 may be connected to two connection electrodes CE1 and CE2 through a contact hole. The two connection electrodes CE1 and CE2 may be disposed on the second source electrode S2 with an insulating layer therebetween. For example, the two connection electrodes CE1 and CE2 may be formed of the same material on the same layer as the high power line VDDL and the low power line VSSL.

A first connection electrode CE1 may be connected to a first sub-electrode 200a that functions as one anode through a contact hole, and a second connection electrode CE2 may be connected to a second sub-electrode 200b that functions as the other anode through a contact hole. Accordingly, the first electrodes 200a and 200b of one sub-pixel may be formed of two sub-electrodes 200a and 200b that are spaced apart from each other. The two sub-electrodes 200a and 200b may be driven at the same time, or only one sub-electrode 200a and 200b may be driven by a repair process for solving defects.

The second drain electrode D2 may face the second source electrode S2 and may be connected to the other end of the second active layer A2 through a contact hole.

The second drain electrode D2 is connected to the high power line VDDL through a high power line connection part VDDL_CP. The high power line connection part VDDL_CP is connected to the high power line VDDL through a contact hole. The high power line connection part VDDL_CP may extend in the first direction and may be connected to the second drain electrode D2 of the first to fourth subpixels. The high power line connection part VDDL_CP and the second drain electrode D2 may be formed as one body.

The second source electrode S2 and the second drain electrode D2 may be formed of the same material as the second gate electrode G2, but are not limited thereto.

In some cases, a configuration connected to the high power line VDDL through the high power line connection part VDDL_CP may function as a source electrode, and a configuration connected to the first electrodes 200a and 200b through the connection electrodes CE1 and CE2 may function as a drain electrode.

The second active layer A2 may be connected to the second source electrode S2 and the second drain electrode D2 through a contact hole, respectively, to function as an electron moving channel. The second active layer A2 may be formed of the same material on the same layer as the first active layer A1.

The sensing thin film transistor T3 includes a third gate electrode G3, a third source electrode S3, a third drain electrode D3, and a third active layer A3.

The third gate electrode G3 may be formed of a part of the gate line extension parts GL_EP1, GL_EP2, GL_EP3, and GL_EP4.

The third source electrode S3 may be formed as one body with the second source electrode S2 of the driving thin film transistor T2. Alternatively, the third source electrode S3 may be connected to the light blocking layer LS through a contact hole, and thus may be electrically connected to the second source electrode S2 of the driving thin film transistor T2 through the light blocking layer LS. The third source electrode S3 may be connected to one end of the third active layer A3 through a contact hole.

The third drain electrode D3 may be formed of the same material on the same layer as the third source electrode S3, and may be connected to the other end of the third active layer A3 through a contact hole. In addition, the third drain electrode D3 may be connected to the reference line RL through a contact hole.

The third active layer A3 may be connected to the third source electrode S3 and the third drain electrode D3 through a contact hole, respectively, to function as an electron moving channel. The third active layer A3 may be formed of the same material on the same layer as the first active layer A1.

According to another embodiment of the present disclosure, a plurality of capacitors are disposed in the transmissive area TA.

The capacitor includes a first capacitor electrode Cap1 and a second capacitor electrode Cap2 overlapping each other.

The first capacitor electrode Cap1 is electrically connected to the second gate electrode G2 of the driving thin film transistor T2. For example, the first capacitor electrode Cap1 is electrically connected to the second gate electrode G2 of the driving thin film transistor T2 through a first capacitor electrode extension part Cap1_EP.

The first capacitor electrode extension part Cap1_EP extends from the transmissive area TA to the display area. For example, one end of the first capacitor electrode extension part Cap1_EP may be connected to the first capacitor electrode Cap1 in the transmissive area TA, and the other end of the first capacitor electrode extension part Cap1_EP may be connected to the second gate electrode G2 of the driving thin film transistor T2 through a contact hole in the display area. Alternatively, the other end of the first capacitor electrode extension part Cap1_EP may be connected to the drain electrode D1 of the switching thin film transistor T1 through a contact hole in the display area, thereby being electrically connected to the second gate electrode G2 of the driving thin film transistor T2.

The first capacitor electrode Cap1 and the first capacitor electrode extension part Cap1_EP may be formed as one body with each other. The first capacitor electrode Cap1 and the first capacitor electrode extension portion Cap1_EP are formed of a transmissive electrode through which light may pass. The first capacitor electrode Cap1 and the first capacitor electrode extension part Cap1_EP may be formed of the same material in the same layer as the second active layer A2, for example, an oxide semiconductor material.

The second capacitor electrode Cap2 is electrically connected to the second source electrode S2 or the drain electrode D2 of the driving thin film transistor T2. For example, the second capacitor electrode Cap2 is electrically connected to the second source electrode S2 or the drain electrode D2 of the driving thin film transistor T2 through a second capacitor electrode extension part Cap2_EP.

The second capacitor electrode extension part Cap2_EP extends from the transmissive area TA to the display area. For example, one end of the second capacitor electrode extension part Cap2_EP may be connected to the second capacitor electrode Cap2 in the transmissive area TA, and the other end of the second capacitor electrode extension part Cap2_EP may be connected to the second source electrode S2 or the drain electrode D2 of the driving thin film transistor T2 through a contact hole in the display area.

The second capacitor electrode extension part Cap2_EP may be connected to the second capacitor electrode Cap2 through a contact hole. The second capacitor electrode extension part Cap2_EP may be formed of the same material on the same layer as the gate line GL, and the second capacitor electrode Cap2 may be formed of the same material on the same layer as the connection electrodes CE1 and CE2, for example, a metal oxide such as ITO.

The second capacitor electrode extension portion Cap2_EP may be formed as one body with the second source electrode S2 or the drain electrode D2 of the driving thin film transistor T2.

Since the second capacitor electrode extension part Cap2_EP should extend from the display area to the transmissive area TA across the low power line VSSL, the second capacitor electrode extension part Cap2_EP should be disposed on a different layer from the low power line VSSL. Therefore, considering that the second capacitor electrode Cap2 is disposed on the same layer as the low power line VSSL and the connection electrodes CE1 and CE2, the second capacitor electrode extension part Cap2_EP is formed of a different material on a different layer from the second capacitor electrode Cap2. In this case, the second capacitor electrode Cap2 is formed of a transmissive electrode through which light may pass, and the second capacitor electrode extension part Cap2_EP is not formed of a transmissive electrode.

However, if the low power line VSSL is not disposed on the same layer as the connection electrodes CE1 and CE2, but is disposed on the same layer as the data lines DL1, DL2, DL3, and DL4, the second capacitor electrode extension part Cap2_EP and the second capacitor electrode Cap2 are formed as one body, and may be formed of the same material on the same layer as the connection electrodes CE1 and CE2.

The second capacitor electrode Cap2 may overlap the first capacitor electrode Cap1 in the transmissive area TA, and the second capacitor electrode extension part Cap2_EP may overlap the first capacitor electrode extension part Cap1_EP in the transmissive area TA and the display area.

A capacitor including the capacitor electrodes Cap1 and Cap2 and the capacitor electrode extension parts Cap1, EP, and Cap2_EP may be disposed for each of the sub-pixels SP1, SP2, and SP3. For example, one capacitor may be disposed on a right side of the third sub-pixel SP3 of one pixel, another capacitor may be disposed on a right side of the fourth sub-pixel SP4 of the one pixel, another capacitor may be disposed on a left side of the first sub-pixel SP1 of the other pixel, and another capacitor may be disposed on a left side of the second sub-pixel SP2 of the other pixel.

Therefore, the capacitor electrode extension parts Cap1_EP and Cap2_EP connected to the third and fourth subpixels SP3 and SP4 of the one pixel are connected to a left side of the capacitor electrodes Cap1 and Cap2, and the capacitor electrode extension parts Cap1_EP and Cap2_EP connected to the first and second subpixels SP1 and SP2 of the other pixel are connected to a right side of the capacitor electrodes Cap1 and Cap2.

In addition, the second capacitor electrode extension part Cap2_EP connected to the third and fourth subpixels SP3 and SP4 of the one pixel may be connected to one of the two connection electrodes CE1 and CE2, for example, the second connection electrode CE2 and the second capacitor electrode extension part Cap2_EP connected to the first and second subpixels SP1 and SP2 of the other pixel may be connected to the other of the two connection electrodes CE1 and CE2, for example, the first connection electrode CE1.

As described above, in accordance with an embodiment of this disclosure, since the capacitor is disposed to have a large area in the transmissive area TA, a capacitance of the capacitor can be increased, so that a luminance increase effect can be obtained.

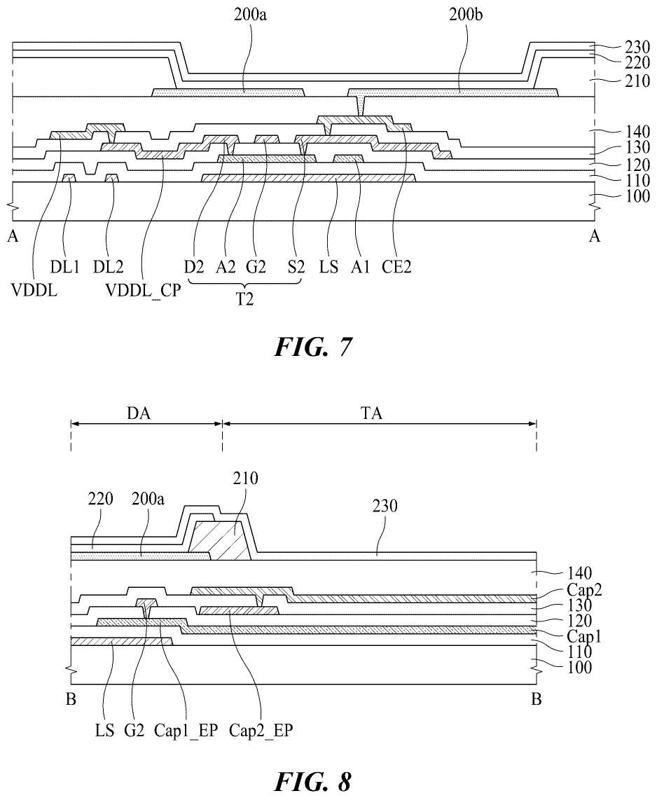

FIG. 7 is a cross-sectional view of an electroluminescent display device according to another embodiment of the present disclosure, which corresponds to a cross-section taken along line A-A of FIG. 6.

As shown in FIG. 7, the data lines DL1 and DL2 and the light blocking layer LS are disposed on the substrate 100 to be spaced apart from each other.

The substrate 100 may be made of glass or plastic, but is not limited thereto. The electroluminescent display device according to an embodiment of the present disclosure may be made of a top emission type, and accordingly, a transparent material may be used as a material of the substrate 100.

The data lines DL1 and DL2 and the light blocking layer LS may be patterned through the same process in the same layer using the same material.

A first insulating layer 110 is disposed on the data lines DL1 and DL2 and the light blocking layer LS.

The first insulating layer 110 may be disposed on an entire surface of the substrate 100 except for the contact hole area. The first insulating layer 110 may be formed of an inorganic insulating material.

A second active layer A2 and a first active layer A1 are disposed on the first insulating layer 110.

The second active layer A2 and the first active layer A1 may be formed of the same material through the same process in the same layer.

At least a portion of the second active layer A2 and the first active layer A1 may overlap the light blocking layer LS, so that light entering under the substrate 100 may be blocked by the light blocking layer LS to prevent the light from entering at least a portion of the second active layer A2 and the first active layer A1.

A second insulating layer 120 is disposed on the second active layer A2 and the first active layer A1.

The second insulating layer 120 may be disposed on the entire surface of the substrate 100 except for a contact hole area. However, the present disclosure is not limited thereto, and the second insulating layer 120 may be formed in the same pattern as a high power line connection part VDDL_CP, a second drain electrode D2, a second gate electrode G2, and a second source electrode S2 except for the contact hole area.

The second insulating layer 120 may be made of an inorganic insulating material.

The high power line connection part VDDL_CP, the second drain electrode D2, the second gate electrode G2, and the second source electrode S2 are disposed on the second insulating layer 120 to be spaced apart from each other.

The high power line connection part VDDL_CP may be formed as one body with the second drain electrode D2.

The second drain electrode D2 overlaps the second active layer A2, and is connected to one end of the second active layer A2 through a contact hole disposed in the second insulating layer 120.

The second gate electrode G2 overlaps the second active layer A2, and is disposed in an area between the second drain electrode D2 and the second source electrode S2.

The second source electrode S2 overlaps the second active layer A2, and is connected to the other end of the second active layer A2 through a contact hole disposed in the second insulating layer 120. The second source electrode S2 may overlap the first active layer A1, but is not connected to the first active layer A1.

The high power line connection part VDDL_CP, the second drain electrode D2, the second gate electrode G2, and the second source electrode S2 may be patterned through the same process in the same layer of the same material.

A third insulating layer 130 may be disposed on the high power source line connection part VDDL_CP, the second drain electrode D2, the second gate electrode G2, and the second source electrode S2.

The third insulating layer 130 may be disposed on an entire surface of the substrate 100 except for a contact hole area. The third insulating layer 130 may be made of an inorganic insulating material.

A high power line VDDL and a second connection electrode CE2 are disposed on the third insulation layer 130.

The high power line VDDL and the second connection electrode CE2 may be patterned using the same material through the same process in the same layer.

The high power line VDDL may be connected to the high power line connection part VDDL_CP through a contact hole disposed in the third insulating layer 130, and the second connection electrode CE2 may be connected to the second source electrode S2 through a contact hole disposed in the third insulating layer 130.

Thus, the high power line VDDL overlaps the high power line connection part VDDL_CP, and the second connection electrode CE2 overlaps the second source electrode S2.

A fourth insulating layer 140 is disposed on the high power source line VDDL and the second connection electrode CE2. The fourth insulating layer 140 may include a planarization layer made of an organic insulating material. The fourth insulating layer 140 may be formed of a plurality of insulating layers, and for example, may have a two-layer structure including a passivation layer made of an inorganic material and a planarization layer made of an organic material.

A first electrode 200a and 200b and a bank 210 are disposed on the fourth insulation layer 140.

Each of the first electrodes 200a and 200b may include a first sub-electrode 200a and a second sub-electrode 200b that are spaced apart from each other while functioning as an anode. The second sub-electrode 200b is connected to the second connection electrode CE2 through a contact hole disposed on the fourth insulation layer 140. Therefore, the second sub-electrode 200b is electrically connected to the second source electrode S2 through the second connection electrode CE2. In some cases, the second sub-electrode 200b may be electrically connected to the second drain electrode D2 through the second connection electrode CE2.

The first electrodes 200a and 200b may include reflective electrodes. Accordingly, light emitted from the light emitting layer 220 may be reflected from the first electrodes 200a and 200b and may proceed in an upward direction.

The bank 210 is disposed on the fourth insulation layer 140 while covering both ends of the first electrode 200a and 200b. A portion of the first electrode 200a and 200b exposed without being covered by the bank 210 may be a light emitting area.

Although not illustrated, the bank 210 may be formed to additionally cover a spaced area between the first sub-electrode 200a and the second sub-electrode 200b.

A light emitting layer 220 is disposed on the first electrodes 200a and 200b and the bank 210, and a second electrode 230 is disposed on the light emitting layer 220.

The light emitting layer 220 may be continuous without being disconnected between the plurality of sub-pixels, and in this case, the light emitting layer 200 may emit white light. The light emitting layer 220 emitting white light may include a stack including a blue light emitting layer and a stack including a yellow green light emitting layer. The light emitting layer 200 emitting white light may include a stack including a blue light emitting layer, a stack including a green light emitting layer, and a stack including a red light emitting layer.

The light emitting layer 220 may include a blue light emitting layer, a green light emitting layer, and a red light emitting layer patterned for each of the plurality of sub-pixels.

The second electrode 230 may function as a cathode. The second electrode 230 may include a reflective electrode. Accordingly, the light emitted from the light emitting layer 220 may be reflected from the second electrode 230 and may proceed in the downward direction. The second electrode 230 may be entirely disposed on the plurality of sub-pixels and a boundary therebetween.

In addition, an encapsulation layer, a color filter, a touch sensor, and the like may be additionally disposed on the second electrode 230.

FIG. 8 is a cross-sectional view of an electroluminescent display device according to another embodiment of the present disclosure, which corresponds to a cross-section taken along line B-B of FIG. 6.

As can be seen from FIG. 8, a light blocking layer LS is disposed on the substrate 100, and a first insulating layer 110 is disposed on the light blocking layer LS.

A first capacitor electrode Cap1 and a first capacitor electrode extension portion Cap1_EP are disposed on the first insulating layer 110. The first capacitor electrode extension part Cap1_EP extends from a display area DA to a transmissive area TA, and the first capacitor electrode Cap1 is disposed in the transmissive area TA. The first capacitor electrode Cap1 and the first capacitor electrode extension part Cap1_EP are formed as one body.

A second insulating layer 120 is disposed on the first capacitor electrode Cap1 and the first capacitor electrode extension part Cap1_EP, and a second gate electrode G2 of the driving thin film transistor and a second capacitor electrode extension part Cap2_EP are disposed on the second insulating layer 120.

The second gate electrode G2 is connected to the first capacitor electrode extension part Cap1_EP through a contact hole disposed in the second insulating layer 120 in the display area DA.

Although not illustrated, the second capacitor electrode extension part Cap2_EP may be formed as one body with the second source electrode S2 or the second drain electrode D2 of the driving thin film transistor.

The second capacitor electrode extension part Cap2_EP extends from the display area DA to the transmissive area TA.

A third insulating layer 130 is disposed on the second gate electrode G2 and the second capacitor electrode extension part Cap2_EP, and a second capacitor electrode Cap2 is disposed on the third insulating layer 130.

The second capacitor electrode Cap2 is disposed in the transmissive area TA. The second capacitor electrode Cap2 is connected to the second capacitor electrode extension part Cap2_EP through a contact hole disposed in the third insulating layer 130.

The second capacitor electrode extension part Cap2_EP overlaps the first capacitor electrode extension part Cap1_EP in the display area DA, and the second capacitor electrode Cap2 overlaps the first capacitor electrode Cap1 in the transmissive area TA.

A fourth insulating layer 140 is disposed on the second capacitor electrode Cap2. Although not shown, a fifth insulating layer may be additionally disposed on the fourth insulating layer 140.

A first sub-electrode 200a is disposed on the fourth insulating layer 140, and a bank 210 is disposed on the first sub-electrode 200a while covering an end of the first sub-electrode 200a. The bank 210 may be disposed in a boundary area between the display area DA and the transmissive area TA.

A light emitting layer 220 is disposed on the first sub-electrode 200a, and a second electrode 230 is disposed on the light emitting layer 220.

The light emitting layer 220 may extend on the bank 210, and in some cases, may extend to the transmissive area TA. The second electrode 230 extends from the display area DA to the transmissive area TA.

In addition, as in the above-described embodiment, an encapsulation layer, a color filter, and a touch sensor may be additionally disposed on the second electrode 230.

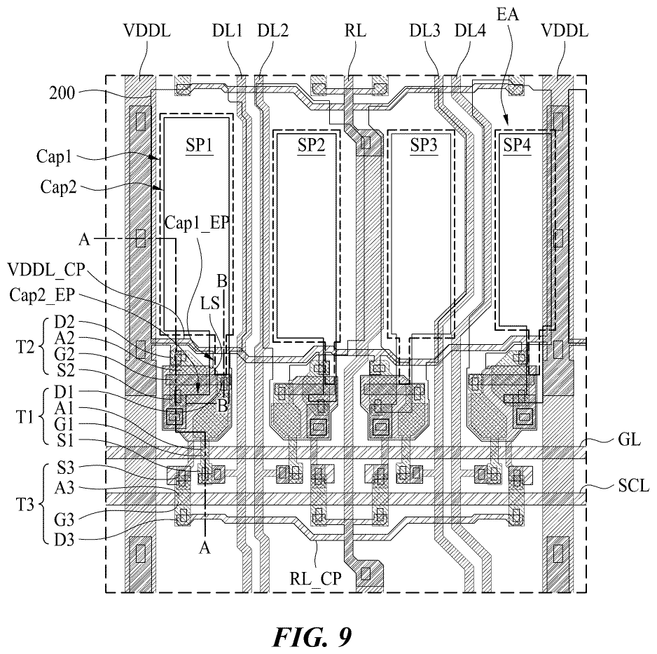

FIG. 9 is a plan view of an electroluminescent display device according to another embodiment of the present disclosure.

As shown in FIG. 2, a gate line GL and a sensing control line SCL are arranged in the first direction, for example, in the horizontal direction.

The gate line GL and the sensing control line SCL may be made of the same material on the same layer.

A high power line VDDL, data lines DL1, DL2, DL3, and DL4 and a reference line RL are arranged in the second direction crossing the first direction, for example, in the vertical direction.

In the second direction, the high power line VDDL, the first data line DL1, the second data line DL2, the reference line RL, the third data line DL3, and the fourth data line DL4 are arranged in order, and the arrangement may be repeated, but is not limited thereto.

The high power line VDDL, the data lines DL1, DL2, DL3, and DL4, and the reference line RL may be formed of the same material on the same layer. The high power line VDDL, the data lines DL1, DL2, DL3, and DL4 and the reference line RL may be positioned below the gate line GL and the sensing control line SCL with an insulating layer therebetween.

A first sub-pixel SP1 may be disposed between the high power line VDDL and the first data line DL1, a second sub-pixel SP2 may be disposed between the second data line DL2 and the reference line RL, a third sub-pixel SP3 may be disposed between the reference line RL and the third data line DL3, and a fourth sub-pixel SP4 may be disposed between the fourth data line DL4 and the high power line VDDL.

The first data line DL1 supplies a data signal to the first sub-pixel SP1, the second data line DL2 supplies a data signal to the second sub-pixel SP2, the third data line DL3 supplies a data signal to the third sub-pixel SP3, and the fourth data line DL4 supplies a data signal to the fourth sub-pixel SP4.

Each of the sub-pixels SP1, SP2, SP3, and SP4 may include a light emitting area, a line area, and a circuit area. In this case, the light emitting area may not overlap the line area and the circuit area, and in this case, the electroluminescence display device may be configured in a bottom emission tyle.

According to another embodiment of the present disclosure, at least a part of the light emitting area, the line area, and the circuit area may constitute a display area in which an image is displayed.

The first data line DL1 and the second data line DL2 may be disposed adjacent to each other without other wirings being disposed therebetween. The third data line DL3 and the fourth data line DL4 may also be disposed adjacent to each other without other wirings being disposed therebetween.

A switching thin film transistor T1, a driving thin film transistor T2, and a sensing thin film transistor T3 are disposed in the circuit area of each of the first to fourth sub-pixels.

The switching thin film transistor T1 includes a first gate electrode G1, a first source electrode S1, a first drain electrode D1, and a first active layer A1.

The first gate electrode G1 may be formed of a part of the gate line GL, but is not limited thereto and may be formed in a structure branched from the gate line GL.

The first source electrode S1 may be connected to a portion branched from the data lines DL1, DL2, DL3, and DL4 through a contact hole, and may be connected to one end of the first active layer A1 through a contact hole.

The first drain electrode D1 may be disposed on the same layer as the first source electrode S1, and may be connected to the other end of the first active layer A1 through a contact hole.

The first source electrode S1 and the first drain electrode D1 may be formed of the same material as the first gate electrode G1, but are not limited thereto.

The first active layer A1 may be connected to the first source electrode S1 and the first drain electrode D1 through a contact hole, respectively, to function as an electron moving channel.

The driving thin film transistor T2 includes a second gate electrode G2, a second source electrode S2, a second drain electrode D2, and a second active layer A2.

The second gate electrode G2 may be connected to the first drain electrode D1 of the switching thin film transistor T1. The second gate electrode G2 may be formed as one body with the first drain electrode D1, but is not limited thereto.

The second source electrode S2 may be connected to one end of the second active layer A2 through a contact hole while facing the second drain electrode D2. The second source electrode S2 may be connected to a light blocking layer LS thereunder through a contact hole.

The light blocking layer LS may be formed of the same material in the same layer as the high power line VDDL, the data lines DL1, DL2, DL3, and DL4, and the reference line RL. The light blocking layer LS may overlap the second active layer A2 to block external light from being incident on the second active layer A2. In addition, the light blocking layer LS may function as a capacitor electrode. Specifically, the light blocking layer LS and the second gate electrode G2 may overlap each other with an insulating layer therebetween, so that a capacitor may be formed by the light blocking layer LS and the second gate electrode G2.

The second source electrode S2 may be connected to the first electrode 200 through a contact hole.

The second drain electrode D2 may face the second source electrode S2 and may be connected to the other end of the second active layer A2 through a contact hole.

The second drain electrode D2 is connected to the high power line VDDL through a high power line connection part VDDL_CP. The high power line connection part VDDL_CP is connected to the high power line VDDL through a contact hole. The high power line connection part VDDL_CP may extend in the first direction and may be connected to the second drain electrode D2 of the first to fourth subpixels. The high power line connection part VDDL_CP and the second drain electrode D2 may be formed as one body.

The second source electrode S2 and the second drain electrode D2 may be formed of the same material as the second gate electrode G2, but are not limited thereto.

In some cases, a configuration connected to the high power line VDDL through the high power line connection part VDDL_CP may function as a source electrode, and a configuration connected to the first electrode 200 may function as a drain electrode.

The second active layer A2 may be connected to the second source electrode S2 and the second drain electrode D2 through a contact hole, respectively, to function as an electron moving channel. The second active layer A2 may be formed of the same material on the same layer as the first active layer A1.

The sensing thin film transistor T3 includes a third gate electrode G3, a third source electrode S3, a third drain electrode D3, and a third active layer A3.

The third gate electrode G3 may be formed as a part of the sensing control line SCL, but is not limited thereto and may be formed in a structure branched from the sensing control line SCL.

The third source electrode S3 may be connected to the light blocking layer LS through a contact hole, and thus may be electrically connected to the second source electrode S2 of the driving thin film transistor T2 through the light blocking layer LS. The third source electrode S3 may be connected to one end of the third active layer A3 through a contact hole while facing the third drain electrode D3.

The third drain electrode D3 may be connected to the other end of the third active layer A3 through a contact hole while facing the third source electrode S3 on the same layer as the third source electrode S3.

The third drain electrode D3 is connected to the reference line RL through a reference line connection part RL_CP.

The reference line connection part RL_CP is connected to the reference line RL through a contact hole. The reference line connection part RL_CP may extend in the first direction and may be connected to the third drain electrode D3 of the first to fourth subpixels. The reference line connection part RL_CP and the third drain electrode D3 may be formed as one body.

The third active layer A3 may be connected to the third source electrode S3 and the third drain electrode D3 through a contact hole, respectively, to function as an electron moving channel. The third active layer A3 may be formed of the same material on the same layer as the first active layer A1.

According to an embodiment of the present disclosure, a plurality of capacitors are disposed in the transmissive area TA.

The capacitor includes a first capacitor electrode Cap1 and a second capacitor electrode Cap2 overlapping each other.

The first capacitor electrode Cap1 is electrically connected to the second gate electrode G2 of the driving thin film transistor T2. For example, the first capacitor electrode Cap1 is electrically connected to the second gate electrode G2 of the driving thin film transistor T2 through a first capacitor electrode extension part Cap1_EP.

The first capacitor electrode extension part Cap1_EP extends from the light emitting area EA to the circuit area. For example, one end of the first capacitor electrode extension part Cap1_EP may be connected to the first capacitor electrode Cap1 in the light emitting area EA, and the other end of the first capacitor electrode extension part Cap1_EP may be connected to the second gate electrode G2 of the driving thin film transistor T2 through a contact hole in the circuit area. Alternatively, the other end of the first capacitor electrode extension part Cap1_EP may be connected to the drain electrode D1 of the switching thin film transistor T1 through a contact hole in the circuit area, thereby being electrically connected to the second gate electrode G2 of the driving thin film transistor T2.

The first capacitor electrode Cap1 and the first capacitor electrode extension part Cap1_EP may be formed as one body with each other. The first capacitor electrode Cap1 and the first capacitor electrode extension part Cap1_EP are formed of a transmissive electrode through which light may pass. The first capacitor electrode Cap1 and the first capacitor electrode extension part Cap1_EP may be formed of the same material in the same layer as the second active layer A2, for example, an oxide semiconductor material.

The second capacitor electrode Cap2 is electrically connected to the second source electrode S2 or the drain electrode D2 of the driving thin film transistor T2. For example, the second capacitor electrode Cap2 is electrically connected to the second source electrode S2 or the drain electrode D2 of the driving thin film transistor T2 through a second capacitor electrode extension part Cap2_EP.

The second capacitor electrode extension part Cap2_EP may extend from the light emitting area EA to the circuit area. For example, one end of the second capacitor electrode extension part Cap2_EP may be connected to the second capacitor electrode Cap2 in the light emitting area EA, and the other end of the second capacitor electrode extension part Cap2_EP may be connected to the second source electrode S2 or the drain electrode D2 of the driving thin film transistor T2 through a contact hole in the circuit area.

The second capacitor electrode Cap2 and the second capacitor electrode extension part Cap2_EP may be formed as one body with each other. The second capacitor electrode Cap2 and the second capacitor electrode extension part Cap2_EP are formed of a transmissive electrode through which light may pass. The second capacitor electrode Cap2 and the second capacitor electrode extension part Cap2_EP may be formed of, for example, a metal oxide such as ITO on the second source electrode S2 or drain electrode D2 of the driving thin film transistor T2.

The second capacitor electrode Cap2 may overlap the first capacitor electrode Cap1 in the light emitting area EA, and the second capacitor electrode extension part Cap2_EP may overlap the first capacitor electrode extension part Cap1_EP in the light emitting area EA and the circuit area.

The capacitor including the capacitor electrodes Cap1 and Cap2 and the capacitor electrode extension parts Cap1, EP, and Cap2_EP may be disposed for each of the sub-pixels SP1, SP2, and SP3.

As described above, in accordance with another embodiment of this disclosure, since the capacitor is disposed to have a large area in the transmissive area TA, a capacitance of the capacitor can be increased, so that a luminance increase effect can be obtained.

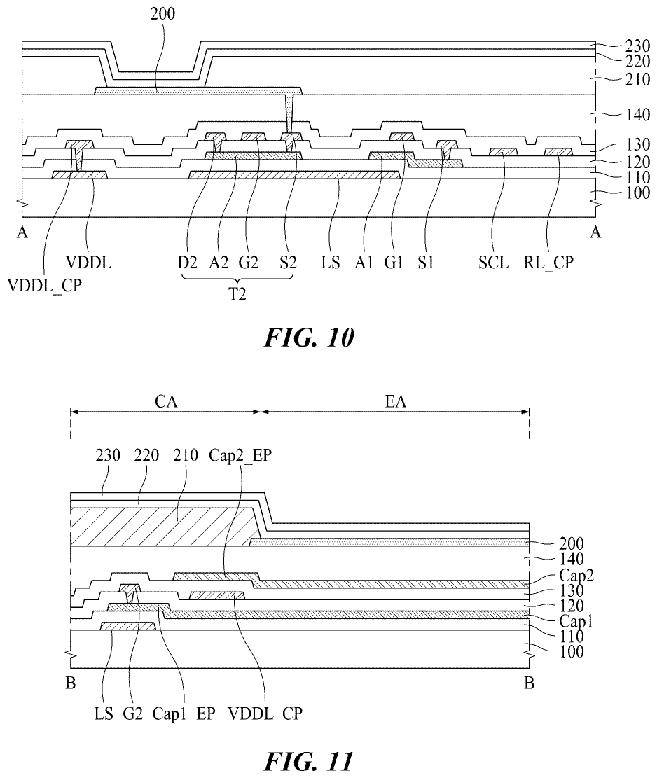

FIG. 10 is a cross-sectional view of an electroluminescent display device according to another embodiment of the present disclosure, which corresponds to a cross-section taken along line A-A of FIG. 9.

As can be seen from FIG. 10, a high power line VDDL and a light blocking layer LS are disposed on the substrate 100 to be spaced apart from each other.

The substrate 100 may be made of glass or plastic, but is not limited thereto. The electroluminescent display device according to an embodiment of the present disclosure may be made of a bottom emission type, and accordingly, a transparent material may be used as a material of the substrate 100.

The high power line VDDL and the light blocking layer LS may be patterned through the same process in the same layer using the same material.

A first insulating layer 110 is disposed on the high power line VDDL and the light blocking layer LS.

The first insulating layer 110 may be disposed on an entire surface of the substrate 100 except for the contact hole area. The first insulating layer 110 may be formed of an inorganic insulating material.

A second active layer A2 and a first active layer A1 are disposed on the first insulating layer 110 to be spaced apart from each other.

At least a portion of the second active layer A2 and the first active layer A1 may overlap the light blocking layer LS, so that light entering under the substrate 100 may be blocked by the light blocking layer LS to prevent the light from entering at least a portion of the second active layer A2 and the first active layer A1.

The second active layer A2 and the first active layer A1 may be formed of the same material through the same process in the same layer.

A second insulating layer 120 is disposed on the second active layer A2 and the first active layer A1.

The second insulating layer 120 may be disposed on the entire surface of the substrate 100 except for a contact hole area. However, the present disclosure is not limited thereto, and the second insulating layer 120 may be formed in the same pattern as a high power line connection part VDDL_CP, a second drain electrode D2, a second gate electrode G2, a first gate electrode G1, a first source electrode S1, a sensing control line SCL, and a reference line connection part RL_CP except for the contact hole area.

The second insulating layer 120 may be made of an inorganic insulating material.

The high power line connection part VDDL_CP, the second drain electrode D2, the second gate electrode G2, the second source electrode S2, the first gate electrode G1, the first source electrode S1, the sensing control line SCL, and the reference line connection part RL_CP are disposed on the second insulating layer 120 to be spaced apart from each other.

The high power line connection part VDDL_CP overlaps the high power line VDDL and is connected to the high power line VDDL through a contact hole disposed in the first insulating layer 110 and the second insulating layer 120.

The second drain electrode D2 overlaps the second active layer A2, and is connected to one end of the second active layer A2 through a contact hole disposed in the second insulating layer 120.

The second gate electrode G2 overlaps the second active layer A2, and is disposed in an area between the second drain electrode D2 and the second source electrode S2.

The second source electrode S2 overlaps the second active layer A2, and is connected to the other end of the second active layer A2 through a contact hole disposed in the second insulating layer 120.

The first gate electrode G1 overlaps the first active layer A1.

The first source electrode S1 overlaps the first active layer A1, and is connected to the first active layer A1 through a contact hole disposed in the second insulating layer 120.

The sensing control line SCL may be disposed between the first source electrode S1 and the reference line connection part RL_CP.

The high power line connection part VDDL_CP, the second drain electrode D2, the second gate electrode G2, the second source electrode S2, the first gate electrode G1, the first source electrode S1, the sensing control line SCL, and the reference line connection part RL_CP may be patterned through the same process in the same layer using the same material.

A third insulating layer 130 may be disposed on the high power source line connection part VDDL_CP, the second drain electrode D2, the second gate electrode G2, the first gate electrode G1, the first source electrode S1, the sensing control line SCL, and the reference line connection part RL_CP, and a fourth insulating layer 140 may be disposed on the third insulating layer 130.

The third insulating layer 130 may be made of an inorganic insulating material.

The fourth insulating layer 140 may include a planarization layer made of an organic insulating material. The fourth insulating layer 140 may be formed of a plurality of insulating layers, and for example, may have a two-layer structure including a passivation layer made of an inorganic material and a planarization layer made of an organic material.

A first electrode 200 and a bank 210 are disposed on the fourth insulating layer 140.

The first electrode 200 may function as an anode. The first electrode 200 is connected to the second source electrode S2 through a contact hole disposed in the third insulating layer 130 and the fourth insulating layer 140. In some cases, the first electrode 200 may be connected to the second drain electrode D2 through a contact hole disposed in the third insulating layer 130 and the fourth insulating layer 140.

The first electrode 200 may include a transparent electrode or a translucent electrode. Accordingly, light emitted from a light emitting layer 220 may pass through the first electrode 200 and may proceed in a downward direction.

The bank 210 is disposed on the third insulation layer 130 while covering both ends of the first electrode 200. A portion of the first electrode 200 exposed without being covered by the bank 210 may be a light emitting area.

A light emitting layer 220 is disposed on the first electrode 200 and the bank 210, and a second electrode 230 is disposed on the light emitting layer 220.

The second electrode 230 may function as a cathode. The second electrode 230 may include a reflective electrode. Accordingly, the light emitted from the light emitting layer 220 may be reflected from the second electrode 230 and may proceed in the downward direction. The second electrode 230 may be entirely disposed on the plurality of sub-pixels and a boundary therebetween.

As in other embodiments, an encapsulation layer, a color filter, a touch sensor, and the like may be additionally disposed on the second electrode 230.

FIG. 11 is a cross-sectional view of an electroluminescent display device according to another embodiment of the present disclosure, which corresponds to a cross-section taken along line B-B of FIG. 9.

As can be seen from FIG. 11, a light blocking layer LS is disposed on the substrate 100, and a first insulating layer 110 is disposed on the light blocking layer LS.

A first capacitor electrode Cap1 and a first capacitor electrode extension portion Cap1_EP are disposed on the first insulating layer 110. The first capacitor electrode extension part Cap1_EP extends from a circuit area CA to a light emitting area EA, and the first capacitor electrode Cap1 is disposed in the light emitting area EA. The first capacitor electrode Cap1 and the first capacitor electrode extension part Cap1_EP are formed as one body.

A second insulating layer 120 is disposed on the first capacitor electrode Cap1 and the first capacitor electrode extension part Cap1_EP, and a second gate electrode G2 of the driving thin film transistor and a high power line connection part VDDL-CP are disposed on the second insulating layer 120.

The second gate electrode G2 is connected to the first capacitor electrode extension part Cap1_EP through a contact hole disposed in the second insulating layer 120 in the circuit area CA.

A third insulating layer 130 is disposed on the second gate electrode G2 and the high power line connection portion VDDL-CP, and a second capacitor electrode Cap2 and a second capacitor electrode extension part Cap2_EP are disposed on the third insulating layer 130.

The second capacitor electrode Cap2 is disposed in the light emitting area EA.

The second capacitor electrode extension part Cap2_EP extends from the circuit area CA to the light emitting area EA.

Although not shown, the second capacitor electrode extension part Cap2_EP is connected to the source electrode S2 or the drain electrode D2 of the driving thin film transistor through a contact hole disposed in the third insulating layer 130.

The second capacitor electrode Cap2 and the second capacitor electrode extension part Cap2_EP are formed as one body.

The second capacitor electrode extension part Cap2_EP overlaps the first capacitor electrode extension part Cap1_EP in the circuit area CA, and the second capacitor electrode Cap2 overlaps the first capacitor electrode Cap1 in the light emitting area EA.

A fourth insulating layer 140 is disposed on the second capacitor electrode Cap2 and the second capacitor electrode extension part Cap2_EP.

A first electrode 200 is disposed on the fourth insulating layer 140, and a bank 210 is disposed on the first electrode 200 while covering an end of the first electrode 200.

The bank 210 is disposed in the circuit area CA and is not disposed in the light emitting area EA.

The first electrode 200 is disposed in the light emitting area EA.

A light emitting layer 220 is disposed on the first electrode 200, and a second electrode 230 is disposed on the light emitting layer 220.

The light emitting layer 220 may be disposed in the light emitting area EA and may extend on the bank 210 to also be disposed in the circuit area CA, but is not limited thereto.

In addition, as in the above-described embodiment, an encapsulation layer, a color filter, and a touch sensor may be additionally disposed on the second electrode 230.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area and a transmissive area;
a plurality of sub-pixels disposed in the display area on the substrate;
a driving thin film transistor disposed in each of the plurality of sub-pixels, the driving thin film transistor including a gate electrode, a source electrode, a drain electrode, and an active layer;
a first electrode disposed in each of the plurality of sub-pixels and electrically connected to either the source electrode or the drain electrode; and
a plurality of capacitors including a first capacitor electrode electrically connected to the gate electrode, and a second capacitor electrode electrically connected to either the source electrode or the drain electrode,
wherein the first capacitor electrode and the second capacitor electrode overlap each other in the transmissive area.

2. The display device of claim 1,
wherein each of the plurality of capacitors further includes:
a first capacitor electrode extension part extending from the display area to the transmissive area and connecting the gate electrode with the first capacitor electrode; and
a second capacitor electrode extension part extending from the display area to the transmissive area and connecting the source electrode or the drain electrode with the second capacitor electrode.

3. The display device of claim 2, wherein the first capacitor electrode extension part and the second capacitor electrode extension part overlap each other in the display area and the transmissive area.

4. The display device of claim 2, wherein the first capacitor electrode and the first capacitor electrode extension part are formed as one body, and the second capacitor electrode and the second capacitor electrode extension part are formed as one body.

5. The display device of claim 2, wherein the first capacitor electrode and the first capacitor electrode extension part are formed as one body, and the second capacitor electrode and the second capacitor electrode extension part are connected to each other through a contact hole.

6. The display device of claim 1, wherein the first capacitor electrode is formed of a same material on a same layer as the active layer.

7. The display device of claim 1, wherein the second capacitor electrode is disposed above either the source electrode or the drain electrode.

8. The display device of claim 1, further comprising at least one connection electrode connecting either the source electrode or the drain electrode with the first electrode, and
wherein the at least one connection electrode is formed of a same material on a same layer as the second capacitor electrode.

9. The display device of claim 8, wherein the at least one connection electrode and the second capacitor electrode are formed as one body.

10. The display device of claim 8, wherein the at least one connection electrode is connected to the second capacitor electrode through a second capacitor electrode extension part, and
wherein the second capacitor electrode extension part is formed of a same material on a same layer as the gate electrode.

11. The display device of claim 1, wherein the first electrode includes a first sub-electrode and a second sub-electrode spaced apart from each other,
wherein the first sub-electrode is electrically connected to either the source electrode or the drain electrode through a first connection electrode, and the second sub-electrode is electrically connected to either the source electrode or the drain electrode through a second connection electrode, and
wherein the second capacitor electrode constituting one capacitor of the plurality of capacitors is connected to the first connection electrode.

12. The display device of claim 11, wherein the second capacitor electrode constituting the other capacitor of the plurality of capacitors is connected to the second connection electrode.

13. The display device of claim 2, wherein the plurality of sub-pixels include a first sub-pixel and a second sub-pixel adjacent to each other,
wherein at least a portion of the driving thin film transistor of the second sub-pixel overlaps the first sub-pixel, and
wherein the second capacitor electrode extension part is disposed between the at least a portion of the driving thin film transistor of the second sub-pixel and the first electrode of the first sub-pixel.

14. The display device of claim 12, further comprising a shielding layer disposed between the second capacitor electrode extension part and the first electrode of the second sub-pixel.

15. A display device comprising:
a substrate including a circuit area and a light emitting area;
a plurality of sub-pixels on the substrate;
a driving thin film transistor disposed in each of the plurality of sub-pixels, the driving thin film transistor including a gate electrode, a source electrode, a drain electrode, and an active layer;
a first electrode disposed in each of the plurality of sub-pixels and electrically connected to either the source electrode or the drain electrode; and
a capacitor including a first capacitor electrode electrically connected to the gate electrode, and a second capacitor electrode electrically connected to either the source electrode or the drain electrode,
wherein the first capacitor electrode and the second capacitor electrode overlap each other in the light emitting area.

16. The display device of claim 15,
wherein the capacitor further includes:
a first capacitor electrode extension part extending from the circuit area to the light emitting area and connecting the gate electrode with the first capacitor electrode; and
a second capacitor electrode extension part extending from the circuit area to the light emitting area and connecting either the source electrode or the drain electrode with the second capacitor electrode.

17. The display device of claim 16, wherein the first capacitor electrode extension part and the second capacitor electrode extension part overlap each other in the circuit area and the light emitting area.

18. The display device of claim 16, wherein the first capacitor electrode and the first capacitor electrode extension part are formed as one body, and the second capacitor electrode and the second capacitor electrode extension part are formed as one body.

19. The display device of claim 16, wherein the first capacitor electrode and the first capacitor electrode extension part are formed of a same material on a same layer as the active layer.

20. The display device of claim 16, wherein the second capacitor electrode and the second capacitor electrode extension part are disposed above either the source electrode or the drain electrode.
